(19) United States
(12) Patent Application Publication
(10) Pub. No.: US 2017/0090003 A1
(43) Pub. Date: Mar. 30, 2017

(54) EFFICIENT TESTING OF MAGNETOMETER SENSOR ASSEMBLIES

(71) Applicant: Apple Inc., Cupertino, CA (US)

(72) Inventor: Jian Guo, Milpitas, CA (US)

(21) Appl. No.: 15/236,137

(22) Filed: Aug. 12, 2016

Related U.S. Application Data
(60) Provisional application No. 62/235,463, filed on Sep. 30, 2015.

(51) Int. Cl. G01R 35/00

(52) U.S. Cl. CPC G01R 35/00

(57) ABSTRACT

Systems, methods, and computer-readable media for efficiently testing sensor assemblies are provided. A test station may be operative to test a three-axis magnetometer sensor assembly by holding the assembly at each one of three test orientations with respect to an electromagnet axis. At each particular test orientation for each particular sensor axis, a difference may be determined between any magnetic field sensed by that sensor axis during the application of a first magnetic field along the electromagnet axis and any magnetic field sensed by that sensor axis during the application of a second magnetic field along the electromagnet axis. Those determined differences may be leveraged with the magnitudes of the first and second magnetic fields and the vector component of the electromagnet axis on each one of the sensor axes at each one of the test orientations to determine the sensitivity performances for each one of the sensor axes.

### CROSS-REFERENCE TO RELATED APPLICATION(S)

This application claims the benefit of prior filed U.S. Provisional Patent Application No. 62/235,463, filed Sep. 30, 2015, which is hereby incorporated by reference herein in its entirety.

### TECHNICAL FIELD

This disclosure relates to systems, methods, and computer-readable media for efficiently testing sensor assemblies and, more particularly, to systems, methods, and computer-readable media for efficiently testing the sensitivity performance of magnetometer sensor assemblies within user electronic devices.

### BACKGROUND OF THE DISCLOSURE

An electronic device (e.g., a laptop computer, a cellular telephone, etc.) may be provided with a magnetometer assembly for measuring a magnetic property of the device's environment. However, heretofore, testing the sensitivity performance of such a magnetometer assembly has been inefficient.

### SUMMARY OF THE DISCLOSURE

This document describes systems, methods, and computer-readable media for efficiently testing sensor assemblies.

For example, a station for testing a sensor assembly, which includes a first sensor module with magnetic field sensitivity along a first sensor axis, a second sensor module with magnetic field sensitivity along a second sensor axis that is perpendicular to the first sensor axis, and a third sensor module with magnetic field sensitivity along a third sensor axis that is perpendicular to both the first sensor axis and the second sensor axis, may include a pair of electromagnets including a first electromagnet and a second electromagnet that is held in a fixed relationship with respect to the first electromagnet, wherein the pair of electromagnets is operative to generate at least one magnetic field along an electromagnet axis extending between the first electromagnet and the second electromagnet. The station may also include a holder operative to hold the sensor assembly in a fixed relationship with respect to the holder, and a re-orientation subassembly operative to move the holder between a plurality of test orientations with respect to the electromagnet axis. The plurality of test orientations include a first test orientation at which the at least one magnetic field forms three identical angles with the first, second, and third sensor axes when the sensor assembly is held by the holder, a second test orientation at which the at least one magnetic field is both perpendicular to the first sensor axis and in a first plane that comprises the second and third sensor axes when the sensor assembly is held by the holder, and a third test orientation at which the at least one magnetic field is both perpendicular to the third sensor axis and in a first plane that comprises the first and second sensor axes when the sensor assembly is held by the holder.

As another example, a method for testing a sensor assembly, which includes a first sensor module with magnetic field sensitivity along a first sensor axis, a second sensor module with magnetic field sensitivity along a second sensor axis that is perpendicular to the first sensor axis, and a third sensor module with magnetic field sensitivity along a third sensor axis that is perpendicular to both the first sensor axis and the second sensor axis, may include orienting the sensor assembly at each one of three different test orientations with respect to an electromagnet axis extending between a first electromagnet and a second electromagnet. When the sensor assembly is oriented at each one of the three different test orientations, the method may include applying a first magnetic field along the electromagnet axis in a first direction and applying a second magnetic field along the electromagnet axis in a second direction opposite the first direction. For each sensor axis of the first, second, and third sensor axes when oriented at each one of the three different test orientations, the method may also include determining the difference between any magnetic field sensed by that sensor axis during the application of the first magnetic field and any magnetic field sensed by that sensor axis during the application of the second magnetic field. The method may also include defining the matrix elements of a first matrix to include the determined differences, defining the matrix elements of a second matrix to include the main-axis sensitivity performance and each one of the two cross-axis sensitivity performances for each one of the first, second, and third sensor axes, defining the matrix elements of a third matrix to include the vector component of the electromagnet axis on each one of the first, second, and third sensor axes at each one of the three different test orientations, and determining the value of each matrix element of the second matrix by leveraging an equation that sets the first matrix equal to the product of the following factors: the sum of the magnitude of the first magnetic field and the magnitude of the second magnetic field, the third matrix, and the second matrix.

As yet another example, a non-transitory computer-readable medium may be provided for testing a sensor assembly with respect to an electromagnet axis, wherein the sensor assembly includes a first sensor module with magnetic field sensitivity along a first sensor axis, a second sensor module with magnetic field sensitivity along a second sensor axis that is perpendicular to the first sensor axis, and a third sensor module with magnetic field sensitivity along a third sensor axis that is perpendicular to both the first sensor axis and the second sensor axis, the non-transitory computer-readable medium including computer-readable instructions recorded thereon for accessing a first matrix including a plurality of first matrix elements, wherein each first matrix elements is indicative of the difference between any magnetic field sensed by a respective particular sensor axis of the first, second, and third sensor axes of the sensor assembly during the application of a first magnetic field in a first direction along the electromagnet axis when the sensor assembly is positioned at a respective particular test orientation of three different test orientations with respect to the electromagnet and any magnetic field sensed by that respective particular sensor axis during the application of a second magnetic field in a second direction along the electromagnet axis when the sensor assembly is positioned at the respective particular test orientation with respect to the electromagnet, accessing a second matrix including a plurality of second matrix elements, wherein each second matrix elements is indicative of the vector component of the electromagnet axis on a respective one of the first, second, and third sensor axes when the sensor assembly is positioned at a respective one of the three different test orientations with respect to the electromagnet, and utilizing the first matrix, the second matrix, and the sum of the magnitude of the first magnetic field and the magnitude of the second magnetic field to determine the sensitivity performances for each one of the first, second, and third sensor axes.

This Summary is provided only to summarize some example embodiments, so as to provide a basic understanding of some aspects of the subject matter described in this document. Accordingly, it will be appreciated that the features described in this Summary are only examples and should not be construed to narrow the scope or spirit of the subject matter described herein in any way. Unless otherwise stated, features described in the context of one example may be combined or used with features described in the context of one or more other examples. Other features, aspects, and advantages of the subject matter described herein will become apparent from the following Detailed Description, Figures, and Claims.

### BRIEF DESCRIPTION OF THE DRAWINGS

The discussion below makes reference to the following drawings, in which like reference characters may refer to like parts throughout, and in which:

FIG. 1 is a schematic view of an illustrative system including an electronic device with a sensor assembly;

FIG. 1A is a front, left, bottom perspective view of the electronic device of FIG. 1;

FIG. 1B is a back, right, bottom perspective view of the electronic device of FIGS. 1 and 1A;

FIG. 2 is a front, right, top perspective view of a test station of the factory subsystem of the system of FIG. 1;

FIG. 2A is a front, left, bottom perspective view of the test station of FIG. 2;

FIG. 2B is a side elevational view of a portion of the test station of FIGS. 2 and 2A, taken from line of FIG. 2A, but with the electronic device of FIGS. 1-1B being held by a holder of the test station;

FIG. 3 is a front, left, bottom perspective view, similar to FIG. 2A, of a fixed portion of the test station of FIGS. 2-2B and a sensor assembly of the electronic device of FIGS. 1-1B and 2B as held by the holder of the test station (not shown) in a first test orientation with respect to the fixed portion of the test station;

FIG. 3A is a front, left, bottom perspective view, similar to FIGS. 2A and 3, of the fixed portion of the test station of FIGS. 2-3 and the sensor assembly of the electronic device of FIGS. 1-1B, 2B, and 3 as held by the holder of the test station (not shown) in a second test orientation with respect to the fixed portion of the test station;

FIG. 3B is a front, left, bottom perspective view, similar to FIGS. 2A, 3, and 3A, of the fixed portion of the test station of FIGS. 2-3A and the sensor assembly of the electronic device of FIGS. 1-1B and 2B-3A as held by the holder of the test station (not shown) in a third test orientation with respect to the fixed portion of the test station; and

FIGS. 4 and 5 are flowcharts of illustrative processes for testing a sensor assembly.

### DETAILED DESCRIPTION OF THE DISCLOSURE

Systems, methods, and computer-readable media may be provided for efficiently testing sensor assemblies. A test station of a factory subsystem may be operative to test any suitable three-axis sensor assembly that may include a first sensor module with magnetic field sensitivity along a first sensor axis, a second sensor module with magnetic field sensitivity along a second sensor axis that is perpendicular to the first sensor axis, and a third sensor module with magnetic field sensitivity along a third sensor axis that is perpendicular to both the first sensor axis and the second sensor axis (e.g., a three-axis magnetometer sensor assembly). The test station may be operative to hold the sensor assembly at each one of three different test orientations with respect to an electromagnet axis along which different fields may be applied in different directions by the test station (e.g., between two electromagnets of an electromagnet pair). At each particular test orientation for each particular sensor module, a difference between any magnetic field sensed by that sensor axis during the application of a first magnetic field along the electromagnet axis in a first direction and any magnetic field sensed by that sensor axis during the application of a second magnetic field along the electromagnet axis in a second direction may be determined. Those determined differences may be leveraged in combination with the magnitudes of the first and second magnetic fields and the vector component of the electromagnet axis on each one of the first, second, and third sensor axes at each one of the three different test orientations in order to determine the sensitivity performances for each one of the first, second, and third sensor axes (e.g., the main-axis sensitivity performance and each one of the two cross-axis sensitivity performances for each one of the first, second, and third sensor axes). In some embodiments, a first one of the test orientations may be configured such that the electromagnet axis forms three identical angles with the first, second, and third sensor axes when the sensor assembly is held at that first test orientation, while a second one of the test orientations may be configured such that the electromagnet axis is both perpendicular to the first sensor axis and in a first plane that includes the second and third sensor axes when the sensor assembly is held at that second test orientation, and/or while a third one of the test orientations may be configured such that the electromagnet axis is both perpendicular to the third sensor axis and in a first plane that includes the first and second sensor axes when the sensor assembly is held by the holder, whereby such particular test orientations may enable a faster and/or smaller test station.

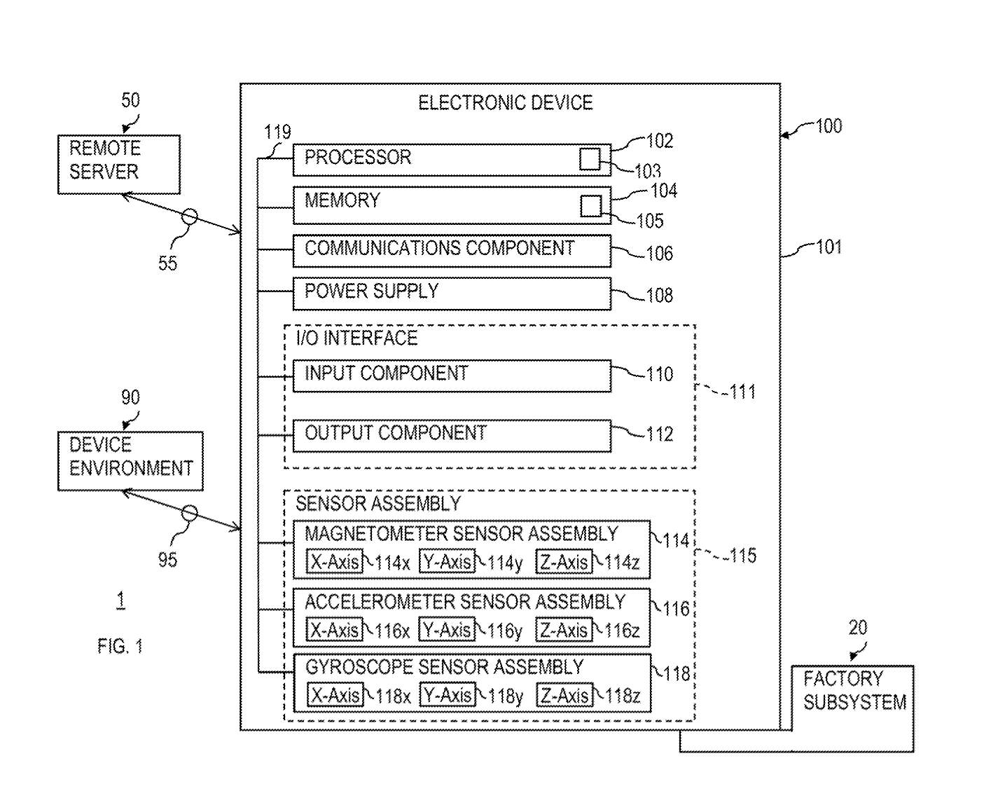

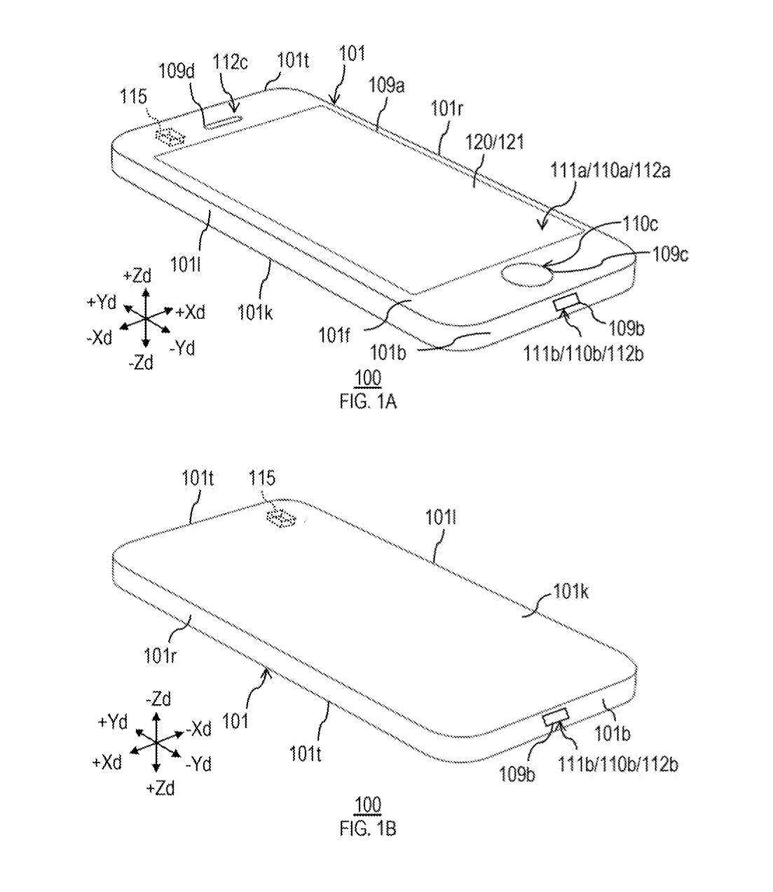

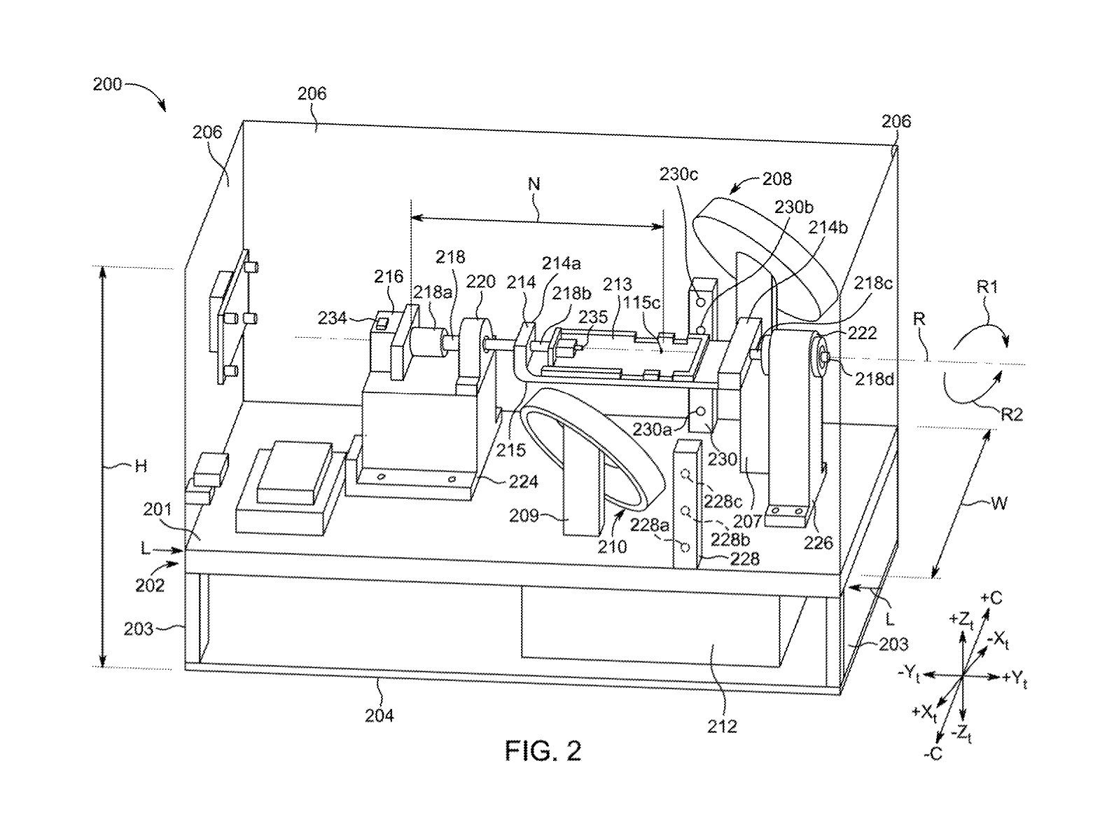

### Description of FIGS. 1-1B

FIG. 1 is a schematic view of a system 1 with an illustrative electronic device 100 that may include a sensor assembly 115, which may operate with low power, high offset stability, low offset, high sensitivity, low sensitivity error, and/or any other suitable high performance properties, for measuring any suitable magnetic property of the device's environment. System 1 may also include a factory subsystem 20 that may include any one or more suitable stations or setups that may be operative to assemble, calibrate, test, and/or package device 100 (e.g., in a factory prior to provisioning device 100 to an end user). For example, factory subsystem 20 may be operative to provide mainline tests, factory functional main test procedures and specifications, factory offline tests (e.g., factory offline coexistence test procedures and specifications), reliability tests, and/or design of experiments coverage for ensuring successful implementation of sensor assembly 115 in electronic device 100.

Electronic device 100 can include, but is not limited to, a music player (e.g., an iPod™ available by Apple Inc. of Cupertino, Calif.), video player, still image player, game player, other media player, music recorder, movie or video camera or recorder, still camera, other media recorder, radio, medical equipment, domestic appliance, transportation vehicle instrument, musical instrument, calculator, cellular telephone (e.g., an iPhone™ available by Apple Inc.), other wireless communication device, personal digital assistant, remote control, pager, computer (e.g., a desktop, laptop, tablet (e.g., an iPad™ available by Apple Inc.), server, etc.), monitor, television, stereo equipment, set up box, set-top box, boom box, modem, router, printer, or any combination thereof. In some embodiments, electronic device 100 may perform a single function (e.g., a device dedicated to measuring a magnetic property of the device's environment) and, in other embodiments, electronic device 100 may perform multiple functions (e.g., a device that measures a magnetic property of the device's environment, plays music, and receives and transmits telephone calls).

Electronic device 100 may be any portable, mobile, hand-held, or miniature electronic device that may be configured to measure a magnetic property of the device's environment wherever a user travels. Some miniature electronic devices may have a form factor that is smaller than that of hand-held electronic devices, such as an iPod™. Illustrative miniature electronic devices can be integrated into various objects that may include, but are not limited to, watches (e.g., an Apple Watch™ available by Apple Inc.), rings, necklaces, belts, accessories for belts, headsets, accessories for shoes, virtual reality devices, glasses, other wearable electronics, accessories for sporting equipment, accessories for fitness equipment, key chains, or any combination thereof. Alternatively, electronic device 100 may not be portable at all, but may instead be generally stationary.

As shown in FIG. 1, for example, electronic device 100 may include a processor 102, memory 104, communications component 106, power supply 108, input component 110, output component 112, and sensor assembly 115. Electronic device 100 may also include a bus 119 that may provide one or more wired or wireless communication links or paths for transferring data and/or power to, from, or between various other components of device 100. In some embodiments, one or more components of electronic device 100 may be combined or omitted. Moreover, electronic device 100 may include any other suitable components not combined or included in FIG. 1 and/or several instances of the components shown in FIG. 1. For the sake of simplicity, only one of each of the components is shown in FIG. 1.

Memory 104 may include one or more storage mediums, including for example, a hard-drive, flash memory, permanent memory such as read-only memory (“ROM”), semi-permanent memory such as random access memory (“RAM”), any other suitable type of storage component, or any combination thereof. Memory 104 may include cache memory, which may be one or more different types of memory used for temporarily storing data for electronic device applications. Memory 104 may be fixedly embedded within electronic device 100 or may be incorporated onto one or more suitable types of components that may be repeatedly inserted into and removed from electronic device 100 (e.g., a subscriber identity module (“SIM”) card or secure digital (“SD”) memory card). Memory 104 may store media data (e.g., music and image files), software (e.g., for implementing functions on device 100), firmware, preference information (e.g., media playback preferences), lifestyle information (e.g., food preferences), exercise information (e.g., information obtained by exercise monitoring equipment), transaction information (e.g., credit card information), wireless connection information (e.g., information that may enable device 100 to establish a wireless connection), subscription information (e.g., information that keeps track of podcasts or television shows or other media a user subscribes to), contact information (e.g., telephone numbers and e-mail addresses), calendar information, pass information (e.g., transportation boarding passes, event tickets, coupons, store cards, financial payment cards, etc.), threshold data (e.g., a set of any suitable threshold data that may be leveraged during testing, such as data 105), any other suitable data, or any combination thereof.

Communications component 106 may be provided to allow device 100 to communicate with one or more other electronic devices or servers of system 1 (e.g., data source or server 50 and/or one or more components of one or more setups of factory subsystem 20, as may be described below) using any suitable communications protocol. For example, communications component 106 may support Wi-Fi™ (e.g., an 802.11 protocol), ZigBee™ (e.g., an 802.15.4 protocol), WiDi™, Ethernet, Bluetooth™, Bluetooth™ Low Energy (“BLE”), high frequency systems (e.g., 900 MHz, 2.4 GHz, and 5.6 GHz communication systems), infrared, transmission control protocol/internet protocol (“TCP/IP”) (e.g., any of the protocols used in each of the TCP/IP layers), Stream Control Transmission Protocol (“SCTP”), Dynamic Host Configuration Protocol (“DHCP”), hypertext transfer protocol (“HTTP”), BitTorrent™, file transfer protocol (“FTP”), real-time transport protocol (“RTP”), real-time streaming protocol (“RTSP”), real-time control protocol (“RTCP”), Remote Audio Output Protocol (“RAOP”), Real Data Transport Protocol™ (“RDTP”), User Datagram Protocol (“UDP”), secure shell protocol (“SSH”), wireless distribution system (“WDS”) bridging, any communications protocol that may be used by wireless and cellular telephones and personal e-mail devices (e.g., Global System for Mobile Communications (“GSM”), GSM plus Enhanced Data rates for GSM Evolution (“EDGE”), Code Division Multiple Access (“CDMA”), Orthogonal Frequency-Division Multiple Access (“OFDMA”), high speed packet access (“HSPA”), multi-band, etc.), any communications protocol that may be used by a low power Wireless Personal Area Network (“6LoWPAN”) module, any other communications protocol, or any combination thereof. Communications component 106 may also include or may be electrically coupled to any suitable transceiver circuitry that can enable device 100 to be communicatively coupled to another device (e.g., a host computer, scanner, accessory device, testing apparatus, etc.), such as server 50 or a suitable component of factory subsystem 20, and to communicate data, such as data 55, with that other device wirelessly, or via a wired connection (e.g., using a connector port). Communications component 106 may be configured to determine a geographical position of electronic device 100 and/or any suitable data that may be associated with that position. For example, communications component 106 may utilize a global positioning system (“GPS”) or a regional or site-wide positioning system that may use cell tower positioning technology or Wi-Fi™ technology, or any suitable location-based service or real-time locating system, which may leverage a geo-fence for providing any suitable location-based data to device 100. As described below in more detail, system 1 may include any suitable remote entity or data source, such as server 50 or a suitable component of factory subsystem 20, that may be configured to communicate any suitable data, such as data 55, with electronic device 100 (e.g., via communications component 106) using any suitable communications protocol and/or any suitable communications medium.

Power supply 108 may include any suitable circuitry for receiving and/or generating power, and for providing such power to one or more of the other components of electronic device 100. For example, power supply 108 can be coupled to a power grid (e.g., when device 100 is not acting as a portable device or when a battery of the device is being charged at an electrical outlet with power generated by an electrical power plant). As another example, power supply 108 may be configured to generate power from a natural source (e.g., solar power using solar cells). As another example, power supply 108 can include one or more batteries for providing power (e.g., when device 100 is acting as a portable device). For example, power supply 108 can include one or more of a battery (e.g., a gel, nickel metal hydride, nickel cadmium, nickel hydrogen, lead acid, or lithium-ion battery), an uninterruptible or continuous power supply (“UPS” or “CPS”), and circuitry for processing power received from a power generation source (e.g., power generated by an electrical power plant and delivered to the user via an electrical socket or otherwise). The power can be provided by power supply 108 as alternating current or direct current, and may be processed to transform power or limit received power to particular characteristics. For example, the power can be transformed to or from direct current, and constrained to one or more values of average power, effective power, peak power, energy per pulse, voltage, current (e.g., measured in amperes), or any other characteristic of received power. Power supply 108 can be operative to request or provide particular amounts of power at different times, for example, based on the needs or requirements of electronic device 100 or periphery devices that may be coupled to electronic device 100 (e.g., to request more power when charging a battery than when the battery is already charged).

One or more input components 110 may be provided to permit a user or device environment to interact or interface with device 100. For example, input component 110 can take a variety of forms, including, but not limited to, a touch pad, dial, click wheel, scroll wheel, touch screen, one or more buttons (e.g., a keyboard), mouse, joy stick, track ball, microphone, camera, scanner (e.g., a barcode scanner or any other suitable scanner that may obtain product identifying information from a code, such as a linear barcode, a matrix barcode (e.g., a quick response (“QR”) code), or the like), proximity sensor, light detector, biometric sensor (e.g., a fingerprint reader or other feature recognition sensor, which may operate in conjunction with a feature-processing application that may be accessible to electronic device 100 for authenticating a user), line-in connector for data and/or power, and combinations thereof. Each input component 110 can be configured to provide one or more dedicated control functions for making selections or issuing commands associated with operating device 100.

Electronic device 100 may also include one or more output components 112 that may present information (e.g., graphical, audible, and/or tactile information) to a user of device 100. For example, output component 112 of electronic device 100 may take various forms, including, but not limited to, audio speakers, headphones, line-out connectors for data and/or power, visual displays (e.g., for transmitting data via visible light and/or via invisible light), infrared ports, flashes (e.g., light sources for providing artificial light for illuminating an environment of the device), tactile/haptic outputs (e.g., rumblers, vibrators, etc.), and combinations thereof. As a specific example, electronic device 100 may include a display assembly output component as output component 112, where such a display assembly output component may include any suitable type of display or interface for presenting visual data to a user with visible light. A display assembly output component may include a display embedded in device 100 or coupled to device 100 (e.g., a removable display). A display assembly output component may include, for example, a liquid crystal display (“LCD”), a light emitting diode (“LED”) display, a plasma display, an organic light-emitting diode (“OLED”) display, a surface-conduction electron-emitter display (“SED”), a carbon nanotube display, a nanocrystal display, any other suitable type of display, or combination thereof. Alternatively, a display assembly output component can include a movable display or a projecting system for providing a display of content on a surface remote from electronic device 100, such as, for example, a video projector, a head-up display, or a three-dimensional (e.g., holographic) display. As another example, a display assembly output component may include a digital or mechanical viewfinder, such as a viewfinder of the type found in compact digital cameras, reflex cameras, or any other suitable still or video camera. A display assembly output component may include display driver circuitry, circuitry for driving display drivers, or both, and such a display assembly output component can be operative to display content (e.g., media playback information, application screens for applications implemented on electronic device 100, information regarding ongoing communications operations, information regarding incoming communications requests, device operation screens, etc.) that may be under the direction of processor 102.

It should be noted that one or more input components and one or more output components may sometimes be referred to collectively herein as an input/output (“I/O”) component or I/O interface (e.g., input component 110 and output component 112 as I/O component or I/O interface 111). For example, input component 110 and output component 112 may sometimes be a single I/O interface 111, such as a touch screen, that may receive input information through a user's touch of a display screen and that may also provide visual information to a user via that same display screen.

Sensor assembly 115 may include any suitable sensor assembly or any suitable combination of sensor assemblies that may be configured independently and/or in combination to detect various types of motion and/or orientation data associated with device 100. For example, as shown, sensor assembly 115 may include a magnetometer or magnetic sensor assembly 114, an accelerometer sensor assembly 116, and/or a gyroscope or angular rate sensor assembly 118. Magnetometer sensor assembly 114 may include any suitable component or combination of components that may be operative to at least partially measure a magnetic property 95 of the environment 90 of electronic device 100 (e.g., to measure the magnetization 95 of a magnetic material 90 proximate device 100, to measure the strength and/or direction of a magnetic field 95 (e.g., along each of one, two, or three axes) at a point in space 90 that may be occupied by or proximal to device 100 (e.g., at a point in space within any suitable setup of factory subsystem 20), etc.) according to any suitable technique (e.g., to provide a compass functionality to device 100 and/or to test sensor assembly 115 and/or to calibrate sensor assembly 115). Magnetometer sensor assembly 114 may include any suitable magnetic sensor, including, but not limited to, any suitable sensor that may utilize magnetoresistance (e.g., the property of a material that may change a value of its electrical resistance when an external magnetic field is applied to the material), such as a magnetoresistive (“MR”) sensor, a giant magnetoresistive (“GMR”) sensor, a tunnel magnetoresistive (“TMR”) sensor, an anisotropic magnetoresistive (“AMR”) sensor, and the like, any suitable sensor that may utilize a superconducting quantum interference device (“SQUID”), any suitable fluxgate magnetometer, any suitable sensor that may utilize a Lorentz force (e.g., using Lorentz force velocimetry (“LFV”), etc.), any other suitable magnetometer, such as a Hall effect magnetometer or Hall effect sensor that may utilize the Hall effect (e.g., the production of a voltage difference across an electrical conductor that may change when a magnetic field perpendicular to a current in the conductor changes), any combinations thereof, and the like. In some embodiments, as shown, magnetometer sensor assembly 114 may include an X-axis magnetometer sensor module 114x that may be operative to measure a direction and/or strength of a magnetic field along a first axis (e.g., an Xs-sensor axis), a Y-axis magnetometer sensor module 114y that may be operative to measure a direction and/or strength of a magnetic field along a second axis (e.g., a Ys-sensor axis that may be perpendicular to the Xs-sensor axis), and/or a Z-axis magnetometer sensor module 114z that may be operative to measure a direction and/or strength of a magnetic field along a third axis (e.g., a Zs-sensor axis that may be perpendicular to the Xs-sensor axis and/or perpendicular to the Zs-sensor axis). For example, magnetometer sensor assembly 114 may be a 3-axis digital magnetometer that may be operative to enable geomagnetic field sensing applications.

Accelerometer sensor assembly 116 may include any suitable component or combination of components that may be operative to at least partially measure a physical acceleration property of electronic device 100 (e.g., to measure the physical acceleration of device 100 relative to the free-fall (e.g., with respect to gravity) along one or more dimensions (e.g., along each of one, two, or three axes)) according to any suitable technique (e.g., to determine a tilt angle of device 100). In some embodiments, as shown, accelerometer sensor assembly 116 may include an X-axis accelerometer sensor module 116x that may be operative to measure a direction and/or strength of an acceleration property along a first axis (e.g., an Xs-sensor axis), a Y-axis accelerometer sensor module 116y that may be operative to measure a direction and/or strength of an acceleration property along a second axis (e.g., a Ys-sensor axis that may be perpendicular to the Xs-sensor axis), and/or a Z-axis accelerometer sensor module 116z that may be operative to measure a direction and/or strength of an acceleration property along a third axis (e.g., a Zs-sensor axis that may be perpendicular to the Xs-sensor axis and/or perpendicular to the Zs-sensor axis). Gyroscope sensor assembly 118 may include any suitable component or combination of components that may be operative to at least partially measure an angular velocity (e.g., angular rate) of electronic device 100 (e.g., to measure the angular velocity of device 100 relative to one or more dimensions (e.g., along one, two, or three rotational axes)) according to any suitable technique (e.g., to determine an orientation of device 100). In some embodiments, as shown, gyroscope sensor assembly 118 may include an X-axis gyroscope sensor module 118x that may be operative to measure a direction and/or strength of an angular velocity along a first rotational axis (e.g., an Xs-sensor axis), a Y-axis gyroscope sensor module 118y that may be operative to measure a direction and/or strength of an angular velocity along a second rotational axis (e.g., a Ys-sensor axis that may be perpendicular to the Xs-sensor axis), and/or a Z-axis gyroscope sensor module 118z that may be operative to measure a direction and/or strength of an angular velocity along a third rotational axis (e.g., a Zs-sensor axis that may be perpendicular to the Xs-sensor axis and/or perpendicular to the Zs-sensor axis).

Processor 102 of electronic device 100 may include any processing circuitry that may be operative to control the operations and performance of one or more components of electronic device 100. For example, processor 102 may receive input signals from input component 110 and/or drive output signals through output component 112. As shown in FIG. 1, processor 102 may be used to run one or more applications, such as an application 103. Application 103 may include, but is not limited to, one or more operating system applications, firmware applications, media playback applications, media editing applications, pass applications, calendar applications, state determination applications, biometric feature-processing applications, compass applications, any other suitable magnetic-detection-based applications, any suitable sensor assembly testing applications, any suitable sensor assembly calibration applications, or any other suitable applications. For example, processor 102 may load application 103 as a user interface program to determine how instructions or data received via an input component 110 or other component of device 100 may manipulate the one or more ways in which information may be stored and/or provided to the user via an output component 112. As another example, processor 102 may load application 103 as a background application program or a user-detectable application program to determine how instructions or data received via sensor assembly 115 and/or server 50 and/or factory subsystem 20 may manipulate the one or more ways in which information may be stored and/or otherwise used to control at least one function of device 100 (e.g., as a magnetic sensor application). Application 103 may be accessed by processor 102 from any suitable source, such as from memory 104 (e.g., via bus 119) or from another device or server (e.g., server 50 and/or factory subsystem 20 and/or any other suitable remote source via communications component 106). Processor 102 may include a single processor or multiple processors. For example, processor 102 may include at least one “general purpose” microprocessor, a combination of general and special purpose microprocessors, instruction set processors, graphics processors, video processors, and/or related chips sets, and/or special purpose microprocessors. Processor 102 also may include on board memory for caching purposes.

Electronic device 100 may also be provided with a housing 101 that may at least partially enclose one or more of the components of device 100 for protection from debris and other degrading forces external to device 100. In some embodiments, one or more of the components may be provided within its own housing (e.g., input component 110 may be an independent keyboard or mouse within its own housing that may wirelessly or through a wire communicate with processor 102, which may be provided within its own housing).

As shown in FIGS. 1A and 1B, a specific example of electronic device 100 may be a handheld electronic device, such as an iPhone™, where housing 101 may allow access to various input components, such as input components 110a, 110b, and 110c, various output components, such as output components 112a, 112b, and 112c, through which device 100 and a user and/or an ambient environment may interface with each other. For example, a touch screen I/O interface 111a may include a display output component 112a and an associated touch input component 110a, where display output component 112a may be used to display a visual or graphic user interface (“GUI”), which may allow a user to interact with electronic device 100. A data and/or power connector interface 111b may include a line-in connector input component 110b for data and/or power and an associated line-out connector output component 112b for data and/or power, where data and/or power may be transmitted from device 100 and/or received by device 100 via connector interface 111b (e.g., a Lightning™ connector by Apple Inc.). Input component 110c may include any suitable button assembly input component that, when pressed, may cause any suitable function (e.g., cause a “home” screen or menu of a currently running application to be displayed by display output component 112a of device 100). Output component 112c may be any suitable audio output component, such as an audio speaker. Any other and/or additional input components and/or output components may be provided by device 100.

Housing 101 may be configured to at least partially enclose each of the input components and output components of device 100. Housing 101 may be any suitable shape and may include any suitable number of walls. In some embodiments, as shown in FIGS. 1A and 1B, for example, housing 101 may be of a generally hexahedral shape and may include a top wall 101t, a bottom wall 101b that may be opposite top wall 101t (e.g., in parallel Xd-Zd planes of the shown Xd-Yd-Zd device coordinates of device 100), a left wall 101l, a right wall 101r that may be opposite left wall 101l (e.g., in parallel Yd-Zd planes of the shown Xd-Yd-Zd device coordinates of device 100), a front wall 101f, and a back wall 101k that may be opposite front wall 101f (e.g., in parallel Xd-Yd planes of the shown Xd-Yd-Zd device coordinates of device 100), where at least a portion of touch screen I/O interface 111a may be at least partially exposed to the external environment via an opening 109a through front wall 101f, where at least a portion of data and/or power connector interface 111b may be at least partially exposed to the external environment via an opening 109b through bottom wall 101b, where at least a portion of button assembly input component 110c may be at least partially exposed to the external environment via an opening 109c through front wall 101f, and where at least a portion of audio speaker assembly output component 112c may be at least partially exposed to the external environment via an opening 109d through front wall 101f. As also shown in broken line in FIGS. 1A and 1B, sensor assembly 115 may be at least partially positioned within housing 101 at any suitable location (e.g., magnetometer sensor assembly 114, accelerometer sensor assembly 116, and gyroscope sensor assembly 118 of sensor assembly 115 may be provided as a single system in package (“SIP”) for colocation within housing 101) or locations (e.g., magnetometer sensor assembly 114, accelerometer sensor assembly 116, and gyroscope sensor assembly 118 of sensor assembly 115 may be provided at different locations within housing 101).

It is to be understood that electronic device 100 may be provided with any suitable size or shape with any suitable number and type of components other than as shown in FIGS. 1A and 1B, and that the embodiments of FIGS. 1A and 1B are only exemplary. It is to be understood that, although housing 101 may be shown and described with respect to Xd-, Yd-, and Zd-device axes, the associated Xs-, Ys-, and Zs-sensor axes for any particular sensor assembly of sensor assembly 115 may be the same as or different than the Xd-, Yd-, and Zd-device axes (e.g., the Xs-sensor axis associated with X-axis magnetometer sensor module 114x of magnetometer sensor assembly 114 may be the same as (e.g., aligned with) or different than (e.g., offset with respect to) the Xd-device axis of housing 101), where such a relationship between the Xd-Yd-Zd device coordinates of device 100 and the Xs-Ys-Zs sensor coordinates of a sensor assembly of sensor assembly 115 may be defined by a device-sensor rotation matrix (e.g., during a calibration procedure).

As mentioned, system 1 may also include factory subsystem 20, which may include any one or more suitable setups that may be operative to assemble, calibrate, test, and/or package device 100 (e.g., in a factory prior to provisioning device 100 to an end user). For example, factory subsystem 20 may be operative to provide mainline tests, factory functional main test procedures and specifications, factory offline tests (e.g., factory offline coexistence test procedures and specifications), reliability tests, and/or design of experiments coverage for ensuring successful implementation of sensor assembly 115 in electronic device 100. Factory subsystem 20 may include any suitable factory mainline or online test stations, including, but not limited to, one or more functional component test stations for any suitable functional component testing (e.g., to verify the functionality of components on a main logic board or other suitable portion of device 100), one or more inertial measurement unit (“IMU”) test stations for any suitable sensor calibrating and/or testing (e.g., to calibrate and test accelerometer sensor assembly 116 and/or gyroscope sensor assembly 118 of sensor assembly 115 in form factor of device 100 on a final assembly, test, and packaging line), one or more burn-in test stations for any suitable sensor interference testing (e.g., to check whether any sensor of sensor assembly 115 may be suffering interference related issues from processing activity on device 100), one or more sensor quick test stations for any suitable sensor performance testing (e.g., to confirm that a sensor meets certain performance specifications but not with the intent to calibrate the sensor in form factor of device 100 on a final assembly, test, and packaging line), and/or one or more sensor coexistence test stations for any suitable sensor coexistence testing (e.g., to identify any device-level issues that may significantly affect output of magnetometer sensor assembly 114). Such functional component testing by any suitable functional component test station(s) may be operative to conduct tests on the main logic board level of device 100 (e.g., to verify that magnetometer sensor assembly 114 provided on such a main logic board (e.g., with diagnostic software) may be operative to communicate with processor 102 (e.g., through diagnostic commands) and/or to verify that any suitable sensor characteristics from magnetometer sensor assembly 114 is near a range of values specified for that sensor assembly (e.g., to extract average output values and/or standard deviations for Xs-, Ys-, and/or Zs-sensor axis sensors of magnetometer sensor assembly 114 and to confirm that such extracted values and deviations as well as any output data rates and/or temperatures of such sensors of magnetometer sensor assembly 114 are within specified ranges)). Such sensor calibrating and/or testing by any suitable IMU station(s) may be operative to calibrate and/or test accelerometer sensor assembly 116 and/or gyroscope sensor assembly 118 of sensor assembly 115 in form factor on a final assembly, test, and packaging line, and/or may be operative to write a compass rotation matrix for mapping raw compass sensor axes (e.g., sensor axes Xs, Ys, Zs) of magnetometer sensor assembly 114 to device axes (e.g., device axes Xd, Yd, Zd) of electronic device 100 (e.g., with respect to housing 101), such as in a device-sensor rotation matrix. Such sensor interference testing by any suitable burn-in test station(s) may be operative to check the power normalized level of any sensor interference. Such sensor performance testing by any suitable sensor quick test station(s) may be operative to ensure that sensor assembly performance (e.g., performance of magnetometer sensor assembly 114) meets any suitable criteria (e.g., for effective software-level offset correction and/or other top-level features). Such sensor coexistence testing by any suitable sensor coexistence test station(s) may be operative to evaluate the impact of various other components of device 100 (e.g., backlight, camera, etc.) on the output of magnetometer sensor assembly 114.

Additionally or alternatively, factory subsystem 20 may include any suitable factory offline test stations, including, but not limited to, one or more system coexistence test stations for any suitable system coexistence testing (e.g., to evaluate the impact of device level static or electromagnetic interference on any magnetometer offset, noise, and/or sensitivity performance), and/or one or more factory design of experiments test stations for any suitable experimental design testing (e.g., Helmholtz coil station design of experiments to evaluate offset, noise, sensitivity, and/or heading performance of magnetometer sensor assembly 114 in a magnetically controlled environment, and/or magnetic survivability station design of experiments to measure device level offset shift, noise, sensitivity impact, and/or heading error performance of device level components before and after device 100 may be exposed to strong external magnetic fields). Such system coexistence testing by any suitable system coexistence test station(s) may be operative to evaluate the impact of various other components of device 100 (e.g., the impact of device level static and/or electromagnetic interference) on the output of magnetometer sensor assembly 114, yet, unlike any coexistence tests carried out at any online test stations, which may be operative to capture only static changes in a magnetic field, such offline test stations may be operative also to capture dynamic effects (e.g., short duration, high current events, etc.). Such experimental design testing by any suitable factory design of experiments test station(s) may be operative to conduct magnetic field sweep with a Helmholtz coil for heading error testing of device 100 in multiple orientations and/or to demagnetize and/or apply a strong magnetic field to device 100 with a magnetic survivability tester.

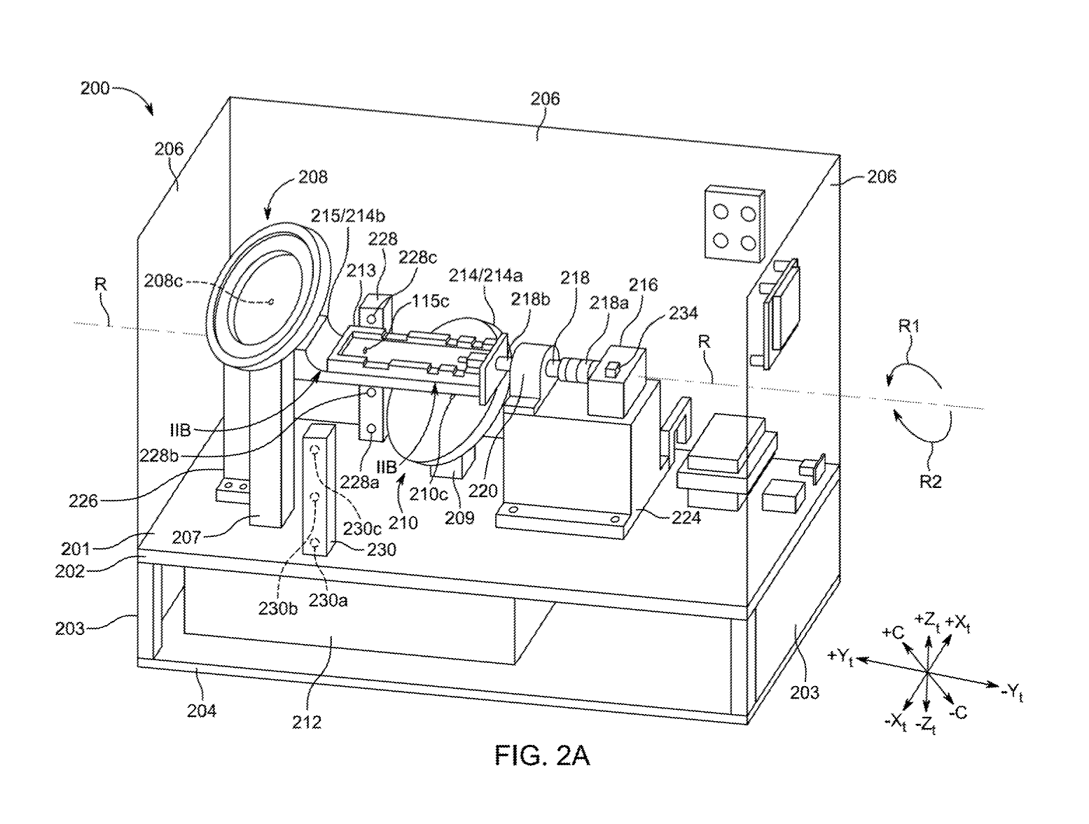

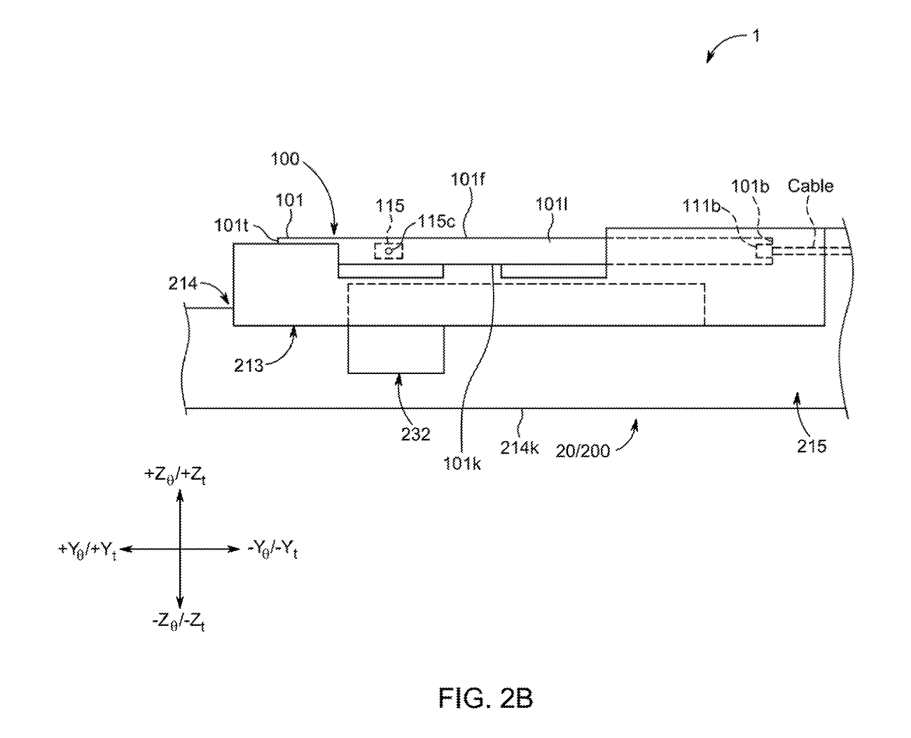

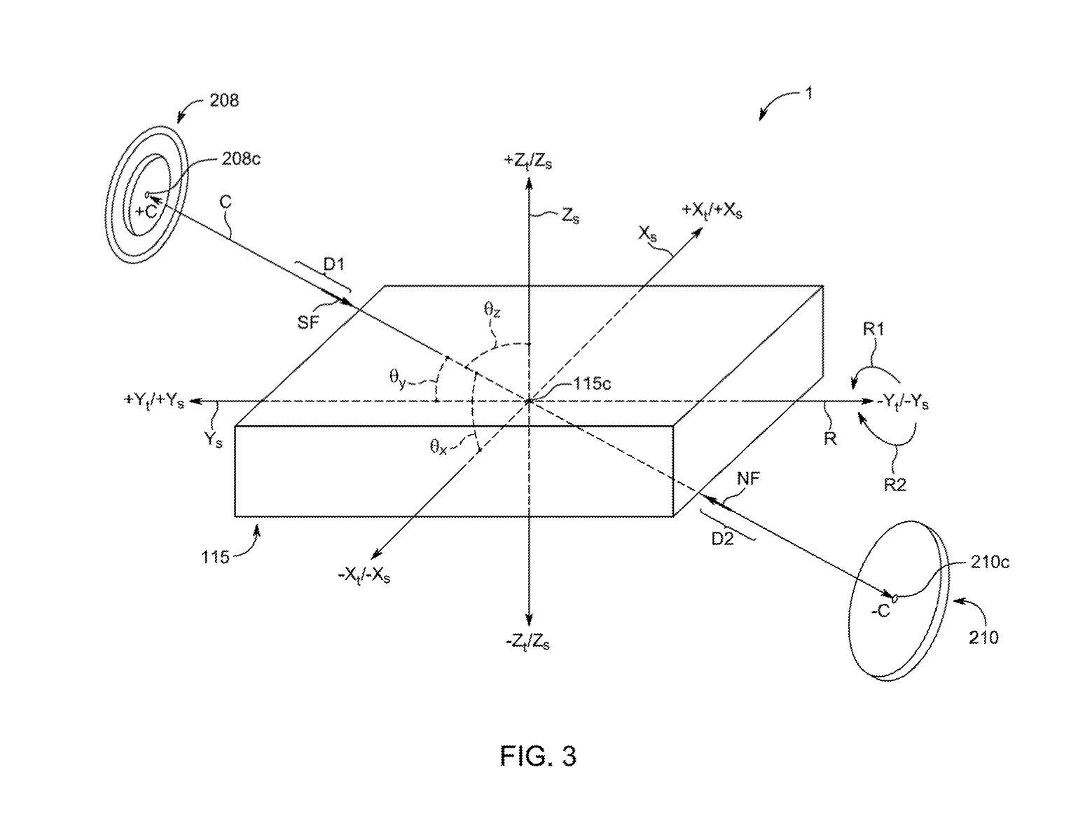

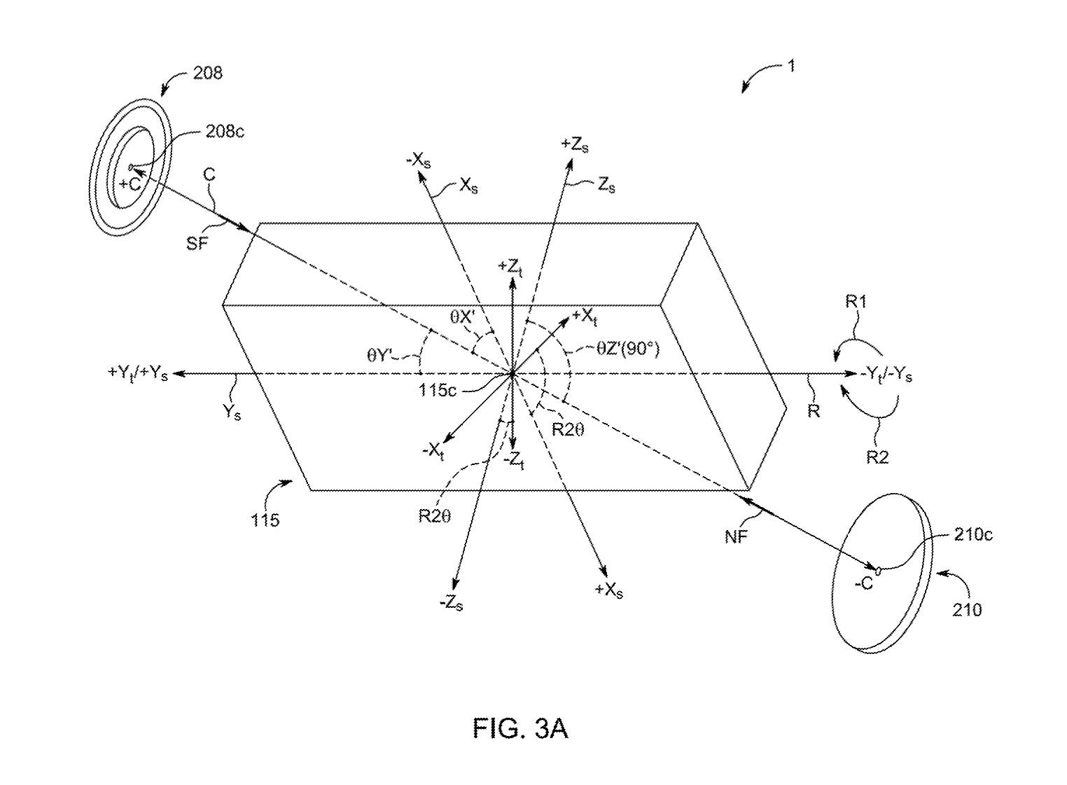

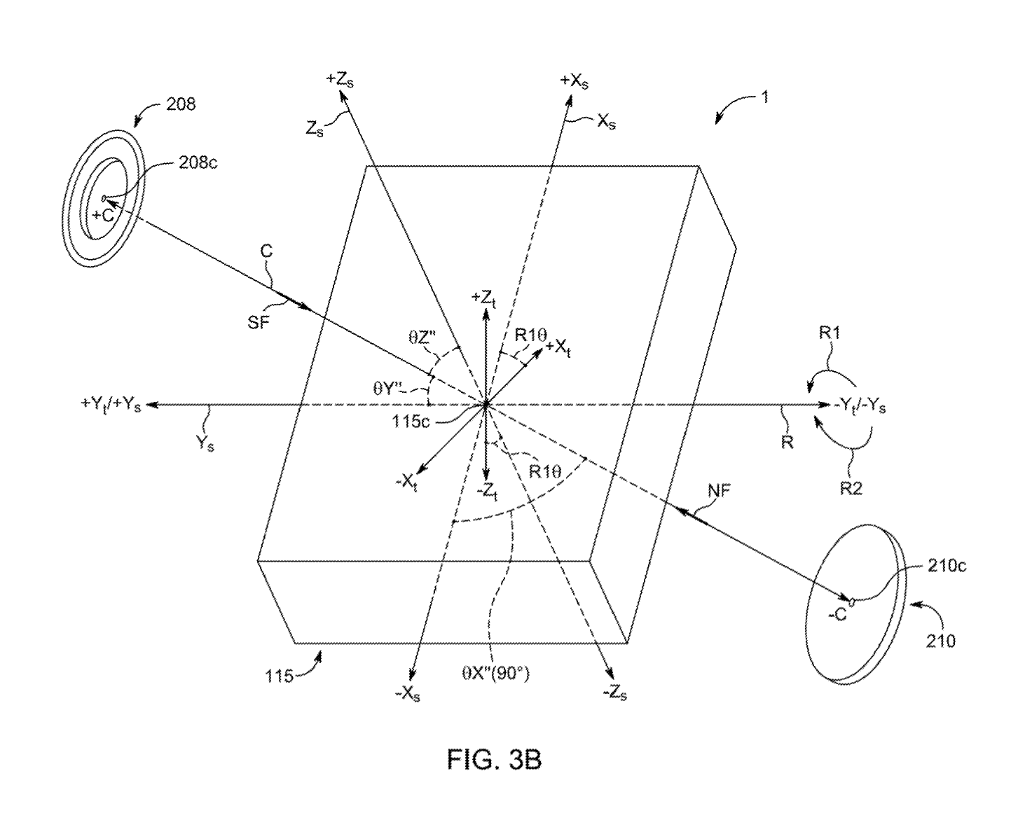

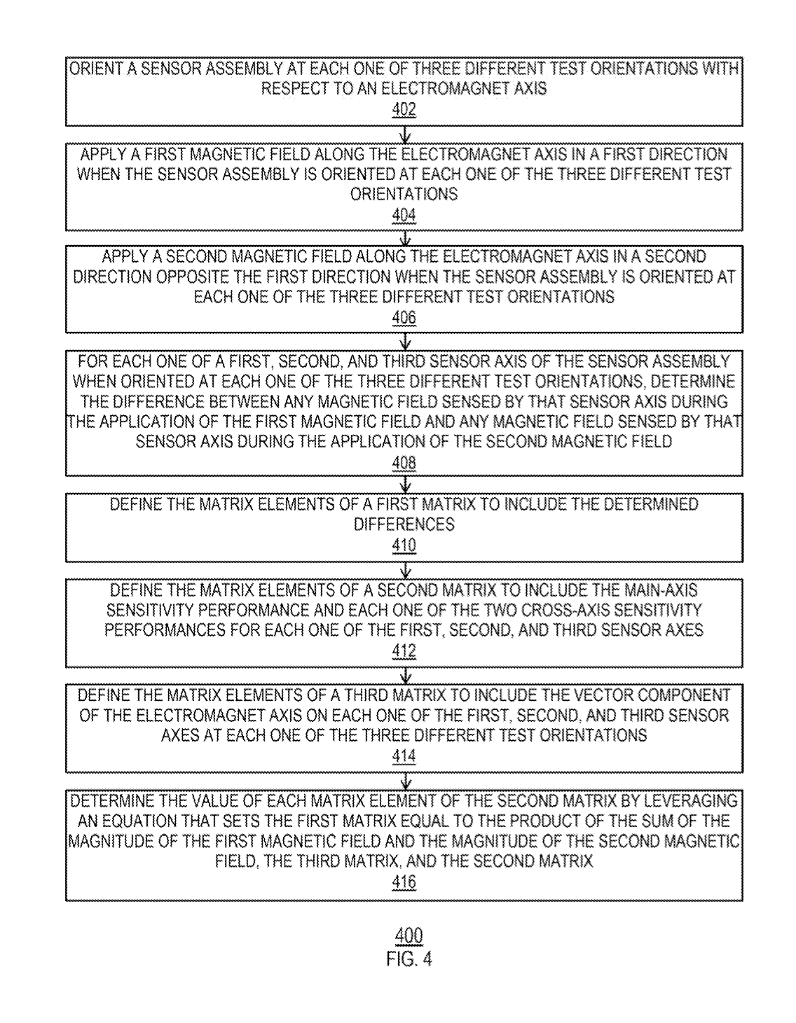

### Description of FIGS. 2-3B

As shown in FIGS. 2-2B, factory subsystem 20 may include a test station 200 that may be operative to test the performance of sensor assembly 115 of electronic device 100. For example, test station 200 may be any suitable factory mainline or online test station, such as a sensor quick test station for any suitable sensor performance testing (e.g., to confirm that magnetometer sensor assembly 114 meets any suitable performance specifications, but not with the intent to calibrate magnetometer sensor assembly 114, while magnetometer sensor assembly 114 is implemented in the form factor of device 100 on a final assembly, test, and packaging line). Test station 200 may be operative to test magnetometer sensor assembly 114 at the device level to enable characterization of the impact of static magnetic or electromagnetic fields on magnetometer sensor assembly 114 within device 100, misalignment of any sensor of magnetometer sensor assembly 114 or of a circuit board on which magnetometer sensor assembly 114 may be provided with respect to housing 101, and/or other sources of variability resulting from the components and assembly of device 100. Certain predefined performance specifications or limits may be compared with data revealed during the testing at test station 200, where such predefined limits may be set to ensure performance of magnetometer sensor assembly 114 meets the criteria for effective software-level offset correction and/or other top-level features of device 100. Test station 200 may be provided at any suitable position along a line of factory subsystem 20 and/or may be used at any suitable time during the assembling, calibrating, testing, and/or packaging of device 100 (e.g., in a factory prior to provisioning device 100 to an end user). For example, test station 200 may be utilized on a mainline (e.g., on a final assembly, test, and packaging line) after any one or more suitable factory mainline or online test stations, such as one or more functional component test stations for any suitable functional component testing, one or more inertial measurement unit test stations for any suitable sensor calibrating and/or testing, and/or one or more burn-in test stations for any suitable sensor interference testing, but may be utilized prior to any suitable offline testing, such as an offline system coexistence test and/or a compass Helmholtz coil station design of experiments test.

Test station 200 may be utilized for testing sensor assembly 115 (e.g., magnetometer sensor assembly 114) once sensor assembly 115 has been fully integrated into device 100 (e.g., within housing 101 of a fully assembled device 100, as shown in FIG. 2B), or may be utilized for testing sensor assembly 115 before integration into device 100. As shown in FIGS. 2 and 2A, test station 200 may include a base component 202 with a front surface 201 that may be any suitable size and shape, such as rectangular with a width W and a length L. Base component 202 may be suspended above a floor 204 with one or more legs 203, and one or more sidewalls 206 may extend upward from floor 204 (e.g., in the +Zt-direction of the shown Xt-Yt-Zt coordinates of test station 200) with a height H. For example, in some embodiments, width W may be 450 millimeters, length L may be 800 millimeters, and height H may be 590 millimeters, although any other suitable dimensions may be possible. Additionally or alternatively, front surface 201 may be substantially planar, such as a surface that may extend along an Xt-Yt plane of the shown Xt-Yt-Zt coordinates of test station 200 (e.g., the fixed Xt-Yt-Zt coordinates of a fixed portion of test station 200, such as base component 202), while each sidewall 206 may extend along different Xt-Zt or Yt-Zt planes of the shown Xt-Yt-Zt coordinates of test station 200.

Test station 200 may also include a pair of any suitable electromagnets or coils (e.g., solenoid electromagnets), such as a first coil 208 (e.g., an up coil or a north coil) and a second coil 210 (e.g., a down coil or a south coil). The position coil 208 may be fixed with respect to the position of coil 210 in any suitable manner. For example, as shown, first coil 208 may be coupled to a first coil support 207 that may extend from front surface 201 of base component 202 at a first location and second coil 210 may be coupled to a second coil support 209 that may extend from front surface 201 of base component 202 at a second location, such that the position of each one of coils 208 and 210 may be fixed with respect to base component 202 and, thus, with respect to the shown Xt-Yt-Zt coordinates of test station 200 and, thus, with respect to each other. Electric charge may be applied to the coils for generating a magnetic field along a coil or electromagnet C-axis that may be common to both coils (e.g., an axis extending between center point 208c of first coil 208 and center point 210c of second coil 210). For example, an electric charge component 212 may be provided (e.g., between base component 202 and floor 204 underneath or proximate one or both of the coils) for alternating between passing a current through coils 208 and 210 (e.g., via coil supports 207/209) in a first direction for generating a particular magnetic field in the +C-direction along the C-axis from coil 210 to coil 208 and passing the current through coils 208 and 210 (e.g., via coil supports 207/209) in a second direction (e.g., reversing the current) for generating the same particular magnetic field in the −C-direction along the C-axis from coil 208 to coil 210. A field applied along the +C-direction away from second coil 210 towards first coil 208 may be referred to as the “North” field, and a field applied along the −C-direction away from first coil 208 towards second coil 210 may be referred to as the “South” field, although it is to be understood that “North” and “South” fields are just relative nomenclature and could instead be referred to as “First” and “Second” fields or “Up” and “Down” fields or “Left” and “Right” fields or the like. Therefore, like the position of each coil of the coil pair, the position of the C-axis of the coil pair may be fixed with respect to the shown Xt-Yt-Zt coordinates of test station 200.

Test station 200 may also include a fixture with a holder 214 that may be operative to hold electronic device 100 or at least a portion thereof, and a re-orientation subassembly (e.g., a subassembly including one or more of a motor 216, a coupler 218, a bearing 220, a bearing 222, etc.) that may be operative to move the holder between multiple different test orientations with respect to the coil C-axis (e.g., to change the position of holder 214 and, thus, at least a portion of device 100 with respect to base component 202 and, thus, with respect to coils 208 and 210 and, thus, with respect to the shown Xt-Yt-Zt coordinates of test station 200). For example, as shown, holder 214 may include a holding portion 213 that may be operative to physically hold any suitable device under test (“DUT”), such as electronic device 100 or at least a sensor assembly thereof, and a supporting portion 215 that may be operative to structurally support holding portion 213 (e.g., for physically interacting with a coupler from motor 216). For example, a first coupler portion 218a of a coupler 218 may be coupled to motor 216 and may extend away from motor 216 along an axis R (e.g., in a +Yt-direction along a Yt-axis of the shown Xt-Yt-Zt coordinates of test station 200) towards a second coupler portion 218b of coupler 218 that may be coupled to holder 214 (e.g., at a first holder side 214a of holder 214). Coupler 218 may further extend from second coupler portion 218b along axis R to a third coupler portion 218c of coupler 218 that may be coupled to holder 214 (e.g., at a second holder side 214b of holder 214). Alternatively, coupler 218 may only be coupled to holder 214 at a single instance or may be coupled to holder 214 along an entire length of holder 214 (e.g., between holder sides 214a and 214b). In some embodiments, as shown, coupler 218 may further extend from third coupler portion 218c along axis R to a fourth coupler portion 218d of coupler 218. Motor 216 may be operative to impart any suitable force onto coupler 218 for rotating coupler 218 (e.g., between first coupler portion 218a and fourth coupler portion 218d) and, thus, holder 214 about axis R in one or both of a first rotational direction R1 about axis R and a second rotational direction R2 about axis R that may be opposite to the direction of first rotational direction R1. A distance N may separate motor 216 from the portion of holder 214 operative to hold the sensor assembly being tested (e.g., the portion of holder 214 operative to hold a sensor assembly center 115c of FIGS. 3-3B), where distance N may be any suitable distance, such as at least 300 millimeters.

One or more bearings may be provided for constraining relative motion of coupler 218 and/or holder 214 to a particular path. For example, as shown, a first bearing 220 may be provided between motor 216 and first holder side 214a of holder 214, and bearing 220 may be operative to enable coupler 218 to pass therethrough or otherwise interact therewith for limiting the motion of coupler 218 to a rotational motion about axis R in one or both of first rotational direction R1 and second rotational direction R2. Additionally or alternatively, a second bearing 222 may be provided adjacent second holder side 214b of holder 214, and bearing 222 may be operative to enable coupler 218 to pass at least therethrough or otherwise interact therewith (e.g., such that a portion of coupler 218 extending between third coupler portion 218c and fourth coupler portion 218d may interact with second bearing 222) for limiting the motion of coupler 218 to the rotational motion about axis R in one or both of first rotational direction R1 and second rotational direction R2. Any suitable materials may be used for providing any suitable bearing of test station 200. For example, first bearing 220 may be at least partially or entirely made of plastic while second bearing 222 may be a follower bearing made of the same material as first bearing 220 or of a different material than first bearing 220. As shown, motor 216 and first bearing 220 may be provided on a first bearing support 224 that may extend from front surface 201 of base component 202 at a first bearing location, while second bearing 222 may be provided on a second bearing support 226 that may extend from front surface 201 of base component 202 at a second bearing location.

Test station 200 may be configured such that holder 214 may be operative to hold at least a portion of sensor assembly 115 (e.g., at least a portion of at least magnetometer sensor assembly 114) of device 100 along the coil C-axis and/or equidistant between coil 208 and coil 210 (e.g., at one, some, or all orientations of holder 214 with respect to the C-axis (e.g., at any rotational orientation of holder 214 with respect to rotational axis R)). For example, as shown in FIGS. 2-3B, when sensor assembly 115 is held by holder 214 at any suitable test orientation with respect to the C-axis, the position of a sensor assembly center 115c of sensor assembly 115 may be maintained on or close to the C-axis of the coil pair in between coil 208 and coil 210. In some embodiments, the position of sensor assembly center 115c may be equidistant between coil 208 and coil 210 on the C-axis at one or each test orientation (e.g., as shown in FIG. 3, distance D1 between sensor assembly center 115c and center point 208c of coil 208 along the C-axis may be the same as distance D2 between sensor assembly center 115c and center point 210c of coil 210 along the C-axis), although in other embodiments or other test orientations distance D1 may be different than distance D2. Sensor assembly center 115c may be the representation of any suitable portion of a sensor assembly, such as the intersection of the multiple sensor axes associated with a particular sensor assembly (e.g., the intersection of the X-sensor axis Xs of X-axis magnetometer sensor module 114x of magnetometer sensor assembly 114, the Y-sensor axis Ys of Y-axis magnetometer sensor module 114y of magnetometer sensor assembly 114, and the Z-sensor axis Zs of Z-axis magnetometer sensor module 114z of magnetometer sensor assembly 114).

The fixed relationship between the C-axis and the Xt-Yt-Zt coordinates of test station 200 may be any suitable relationship. Additionally or alternatively, the relationship between the C-axis and the Xs-Ys-Zs sensor axes of sensor assembly 115 (e.g., the X-sensor axis Xs of X-sensor axis magnetometer sensor module 114x of magnetometer sensor assembly 114, the Y-sensor axis Ys of Y-axis magnetometer sensor module 114y of magnetometer sensor assembly 114, and the Z-sensor axis Zs of Z-axis magnetometer sensor module 114z of magnetometer sensor assembly 114) at any particular rotational orientation of rotatable holder 214 and, thus, of rotatable sensor assembly 115 with respect to fixed base component 202 and, thus, with respect to the fixed C-axis may be any suitable relationship (e.g., any suitable test orientation of holder 214 and sensor assembly 115 with respect to the coil pair C-axis may have any suitable relationship). For example, at a first particular test orientation of holder 214 and sensor assembly 115 with respect to the C-axis, as may be shown in each one of FIGS. 2, 2A, and 3, sensor assembly center 115c may be held such that each axis of magnetometer sensor assembly 114 (e.g., the X-sensor axis Xs of X-sensor axis magnetometer sensor module 114x of magnetometer sensor assembly 114 from +Xs to −Xs, the Y-sensor axis Ys of Y-axis magnetometer sensor module 114y of magnetometer sensor assembly 114 from +Ys to −Ys, and the Z-sensor axis Zs of Z-axis magnetometer sensor module 114z of magnetometer sensor assembly 114 from +Zs to −Zs) may be the same as a respective one of the fixed Xt-Yt-Zt coordinate axes of test station 200 (e.g., of base component 202). That is, when holder 214 and sensor assembly 115 may be held in a first particular test orientation with respect to the C-axis, as shown in each one of FIGS. 2, 2A, and 3, X-sensor axis Xs may be the same as X-test station axis Xt, Y-sensor axis Ys may be the same as Y-test station axis Yt, and Z-sensor axis Zs may be the same as Z-test station axis Zt. Additionally or alternatively, at a first particular test orientation of holder 214 and sensor assembly 115 with respect to the C-axis, as may be shown in each one of FIGS. 2, 2A, and 3, sensor assembly center 115c may be held on the C-axis such that each axis of magnetometer sensor assembly 114 (e.g., the X-sensor axis Xs, the Y-sensor axis Ys, and the Z-sensor axis Zs) may be exposed in equal magnitudes (e.g., equal proportions) to the magnetic field applied by the coil pair on the sensor assembly. This may be enabled by orienting holder 214 and, thus, sensor assembly center 115c with respect to the C-axis in the test orientation of FIGS. 2, 2A, and 3 such that angles formed between the C-axis and each one of the sensor axes of magnetometer sensor assembly 114 may be the same (e.g., such that an angle θX between the C-axis and the X-sensor axis Xs of X-sensor axis magnetometer sensor module 114x, an angle θY between the C-axis and the Y-sensor axis Ys of Y-sensor axis magnetometer sensor module 114y, and an angle θZ between the C-axis and the Z-sensor axis Zs of Z-sensor axis magnetometer sensor module 114z may be equal to one another, such as equal to 54.76°).

Additionally or alternatively, at a second particular test orientation of holder 214 and sensor assembly 115 with respect to the C-axis, as may be shown in FIG. 3A, sensor assembly center 115c may be held on the C-axis such that one particular axis of magnetometer sensor assembly 114 may be perpendicular with the C-axis. For example, as shown in FIG. 3A, at such a second test orientation, sensor assembly center 115c may be held on the C-axis such that the Z-sensor axis Zs of Z-sensor axis magnetometer sensor module 114z may be perpendicular to the C-axis (e.g., such that an angle θZ′ between the C-axis and the Z-sensor axis Zs may be 90°) and such that the C-axis may extend along an Xs-Ys plane in which both the X-sensor axis Xs and the Y-sensor axis Ys may extend, where an angle θX′ may be defined in that Xs-Ys plane between the C-axis and the X-sensor axis Xs, and where an angle θY′ may be defined in that Xs-Ys plane between the C-axis and the Y-sensor axis Ys). Additionally or alternatively, at a third particular test orientation of holder 214 and sensor assembly 115 with respect to the C-axis, as may be shown in FIG. 3B, sensor assembly center 115c may be held on the C-axis such that another particular axis of magnetometer sensor assembly 114 may be perpendicular with the C-axis. For example, as shown in FIG. 3B, at such a third test orientation, sensor assembly center 115c may be held on the C-axis such that the X-sensor axis Xs of X-sensor axis magnetometer sensor module 114x may be perpendicular to the C-axis (e.g., such that an angle θX″ between the C-axis and the X-sensor axis Xs may be 90°) and such that the C-axis may extend along a Ys-Zs plane in which both the Y-sensor axis Ys and the Z-sensor axis Zs may extend, where an angle θY″ may be defined in that Ys-Zs plane between the C-axis and the Y-sensor axis Ys, and where an angle θZ″ may be defined in that Ys-Zs plane between the C-axis and the Z-sensor axis Zs).

Re-orientation of holder 214 and sensor assembly 115 with respect to the C-axis between any three suitable test orientations, such as the test orientations of FIGS. 3, 3A, and 3B, may be enabled by rotating holder 214 and sensor assembly 115 about axis R, which may be aligned with a Y-test station axis Yt of the fixed portion of test station 200 and/or which may be aligned with the Y-sensor axis Ys of Y-sensor axis magnetometer sensor module 114y (e.g., as shown, axis R may be the same as or aligned with Y-sensor axis Ys). For example, holder 214 and sensor assembly 115 may be rotated about axis R in the direction of arrow R2 by any suitable rotation angle R20 (e.g., 45°) for re-orienting holder 214 and sensor assembly 115 with respect to the C-axis from the test orientation of FIG. 3 and/or from the test orientation of FIG. 3B to the test orientation of FIG. 3A, whereby the X-sensor axis Xs of FIG. 3A is offset from the X-test station axis Xt by angle R2θ, and whereby the Z-sensor axis Zs of FIG. 3A is offset from the Z-test station axis Zt by angle R2θ, yet whereby the Y-sensor axis Ys of FIG. 3A is still aligned with the Y-test station axis Yt. Additionally or alternatively, for example, holder 214 and sensor assembly 115 may be rotated about axis R in the direction of arrow R1 by any suitable rotation angle R1θ (e.g., 45°) for re-orienting holder 214 and sensor assembly 115 with respect to the C-axis from the test orientation of FIG. 3 and/or from the test orientation of FIG. 3A to the test orientation of FIG. 3B, whereby the X-sensor axis Xs of FIG. 3B is offset from the X-test station axis Xt by angle R1θ, and whereby the Z-sensor axis Zs of FIG. 3B is offset from the Z-test station axis Zt by angle RIO, yet whereby the Y-sensor axis Ys of FIG. 3B is still aligned with the Y-test station axis Yt. The amount of rotation of holder 214 about any particular axis from a first test orientation to a second test orientation may be the same or different than the amount of rotation of holder 214 about that same particular axis or any other particular axis from the first test orientation and/or from the second test orientation to a third test orientation. It is to be understood that any three suitable test orientations of holder 214 with respect to the coil pair C-axis may be used to test magnetometer assembly 114 as described herein. Therefore, holder 214 may be operative to hold a DUT (e.g., sensor assembly 115 or electronic device 100 including sensor assembly 115) in a particular fixed position and orientation with respect to holder 214, and other components of test station 200 (e.g., motor 216, coupler 218, and/or bearing 220/222) may be operative to adjust the position and/or orientation of holder 214 and its DUT with respect to the C-axis of the coil pair.

Test station 200 may be configured in any suitable manner for enabling proper testing of sensor assembly 115 (e.g., magnetometer sensor assembly 114 as may be coupled (e.g., soldered) on a main logic board of device 100 and as may have passed suitable functional component testing and assembled into the form factor of device 100 in a final assembly, test, and packaging line). For example, a first or north magnetic field NF applied along the C-axis in the +C-direction away from second coil 210 towards first coil 208 may be any suitable magnitude of magnetic field or magnetic flux density, such as 150 microteslas, while a second or south magnetic field SF applied along the C-axis in the −C-direction away from first coil 208 towards second coil 210 may be any suitable magnitude of magnetic field or magnetic flux density, such as 150 microteslas, such that, in some embodiments, a north-minus-south (“NMS”) applied field of the coil pair (e.g., the sum of the absolute values of the magnitudes of the two opposite fields of the coil pair) may be 300 microteslas for ensuring sufficient field strength to test the DUT. Although such an example of a 150 microtesla north magnetic field, a 150 microtesla south magnetic field, and a resulting 300 microtesla NMS magnetic field may be referred to throughout certain portions of this disclosure, it is to be understood that any suitable north magnetic field magnitude and any suitable south magnetic field magnitude may be utilized by test station 200 for carrying out testing of sensor assembly 115. For example, in other embodiments, the magnitude of the north magnetic field may be different than the magnitude of the south magnetic field (e.g., 200 microteslas as compared to 100 microteslas) rather than being the same (e.g., 150 microteslas each). Additionally or alternatively, the magnitude of the NMS magnetic field may be greater than or less than 300 microteslas. For example, the magnitude of the NMS magnetic field may be at least the magnitude of the earth's magnetic field (e.g., 50 microteslas) but may be significantly greater than that (e.g., 300 microteslas) to provide a significant variation with respect to the earth's magnetic field. However, whatever magnitude of the north magnetic field and whatever magnitude of the south magnetic field utilized by the coil pair of test station 200, such magnitudes ought to remain consistent during the testing of sensor assembly 115 at each one of the various test orientations of a particular sensor assembly 115 with respect to such magnetic fields (e.g., to minimize the computational processing required to adequately test the sensor assembly). A maximum electromagnetic field noise for test station may be held under 0.35 microteslas root-mean-square for adequate results. Test station 200 may be checked and calibrated routinely (e.g., daily) for ensuring such performance (e.g., using a reference magnetometer or Gaussmeter, such as an external reference sensor 232, which may be held with respect to holder 214 as close as possible to the sensor assembly of the DUT being tested (e.g., as close as possible to the position of sensor assembly center 115c with respect to holder 214), as shown in FIG. 2B). Moreover, the NMS field angle to the DUT (e.g., to the position of a sensor assembly center 115c of sensor assembly 115) may be set to be equal with respect to each axis of at least an appropriate sensor assembly of sensor assembly 115 (e.g., sensor axes Xs, Ys, and Zs of magnetometer assembly 114), such as 53.76°, at a particular test orientation of holder 214 with respect to the coil C-axis (e.g., the test orientation of FIG. 3). Additionally or alternatively, motor 216 may be configured to generate magnetic interference of less than 2 microteslas when motor 216 is in operation (e.g., when motor 216 is re-orienting holder 214 between the orientations of FIGS. 3, 3A, and 3B).

At each test orientation of holder 214 and the DUT with respect to coil axis C (e.g., each one of the orientations of FIGS. 3, 3A, and 3B), various procedures may be carried out to verify the functionality and proper working condition of the DUT (e.g., magnetometer sensor assembly 114). For example, when holder 214 and sensor assembly 115 are held at a first particular test orientation (“O1”) with respect to the coil pair C-axis (e.g., the test orientation of FIG. 3), one or more of the following procedures may be carried out (e.g., at test station 200):
(1) when no magnetic field is applied by test station 200 along the coil C-axis, a certain number of output data readings from each sensor module of a particular sensor assembly held at the first test orientation O1 may be collected that may be indicative of any magnetic field sensed by each sensor module (e.g., 100 output data readings from each one of X-axis magnetometer sensor module 114x, Y-axis magnetometer sensor module 114y, and Z-axis magnetometer sensor module 114z may be collected when a sample rate of magnetometer sensor assembly 114 is set to 100 hertz and output data is collected for 1 second);
(2) average values of the number of output data readings collected by procedure (1) (e.g., when no magnetic field is applied by test station 200 along the coil C-axis) may be determined for each sensor module held at the first test orientation O1 (e.g., “O1.None.Avg.X” for X-axis magnetometer sensor module 114x, “O1.None.Avg.Y” for Y-axis magnetometer sensor module 114y, and “O1.None.Avg.Z” for Z-axis magnetometer sensor module 114z) (or at each test orientation), and then such average output data values as sensed by the DUT sensor assembly held at the first test orientation O1 (or at each test orientation) may be verified to be within any particular test limits of sensor assembly 114 (e.g., a range between −1200 microteslas to +1200 microteslas for each sensor axis sensor module);
(3) standard deviation values for the output data readings collected by procedure (1) (e.g., when no magnetic field is applied by test station 200 along the coil C-axis) may be determined for each sensor module held at the first test orientation O1 (e.g., “O1.None.Std.X” for X-axis magnetometer sensor module 114x, “O1.None.Std.Y” for Y-axis magnetometer sensor module 114y, and “O1.None.Std.Z” for Z-axis magnetometer sensor module 114z) (or at each test orientation), and then such standard deviation values may be verified to be within any particular test limits of sensor assembly 114 (e.g., a range between 0 microteslas to 0.5 microteslas for each sensor axis sensor module);
(4) when a first or north magnetic field is applied by test station 200 along the +C-direction of the coil C-axis away from second coil 210 towards first coil 208 (e.g., a north magnetic field of 150 microteslas), a certain number of output data readings from each sensor module of a particular sensor assembly held at the first test orientation O1 may be collected that may be indicative of any magnetic field sensed by each sensor module (e.g., 100 output data readings for each one of X-axis magnetometer sensor module 114x, Y-axis magnetometer sensor module 114y, and Z-axis magnetometer sensor module 114z may be collected when a sample rate of magnetometer sensor assembly 114 is set to 100 hertz and output data is collected for 1 second);
(5) average values of the number of output data readings of procedure (4) (e.g., when a first or north magnetic field is applied by test station 200 along the +C-direction of the coil C-axis) may be determined for each sensor module held at the first test orientation O1 (e.g., “O1.North.Avg.X” for X-axis magnetometer sensor module 114x, “O1.North.Avg.Y” for Y-axis magnetometer sensor module 114y, and “O1.North.Avg.Z” for Z-axis magnetometer sensor module 114z), and then such average output data values as sensed by the DUT sensor assembly held at the first test orientation O1 may be verified to be within any particular test limits of sensor assembly 114;
(6) the magnitude of the first magnetic field as sensed by the DUT sensor assembly held at the first test orientation O1 may be calculated using the determined average values of procedure (5), such as by calculating the square root of the sum of the squares of the determined average values of procedure (5) (e.g., “O1.North.Mag”=√((“O1.North.Avg.X”)²+(“O1.North.Avg.Y”)²+(“O1.North.Avg.Z”)²)), and then such a magnitude of the first magnetic field as sensed by the DUT sensor assembly held at the first test orientation O1 may be verified to be within any particular test limits of sensor assembly 114;
(7) when a second or south magnetic field is applied by test station 200 along the −C-direction of the coil C-axis away from first coil 208 towards second coil 210 (e.g., a south magnetic field of 150 microteslas), a certain number of output data readings from each sensor module of a particular sensor assembly held at the first test orientation O1 may be collected that may be indicative of any magnetic field sensed by each sensor module (e.g., 100 output data readings for each one of X-axis magnetometer sensor module 114x, Y-axis magnetometer sensor module 114y, and Z-axis magnetometer sensor module 114z may be collected when a sample rate of magnetometer sensor assembly 114 is set to 100 hertz and output data is collected for 1 second);
(8) average values of the number of output data readings of procedure (7) (e.g., when a second or south magnetic field is applied by test station 200 along the −C-direction of the coil C-axis) may be determined for each sensor module held at the first test orientation O1 (e.g., “O1.South.Avg.X” for X-axis magnetometer sensor module 114x, “O1.South.Avg.Y” for Y-axis magnetometer sensor module 114y, and “O1.South.Avg.Z” for Z-axis magnetometer sensor module 114z), and then such average output data values as sensed by the DUT sensor assembly held at the first test orientation O1 may be verified to be within any particular test limits of sensor assembly 114;
(9) the magnitude of the second magnetic field as sensed by the DUT sensor assembly held at the first test orientation O1 may be calculated using the determined average values of procedure (8), such as by calculating the square root of the sum of the squares of the determined average values of procedure (8) (e.g., “O1.South.Mag”=√((“O1.South.Avg.X”)²+(“O1.South.Avg.Y”)²+(“O1.South.Avg.Z”)²)), and then such a magnitude of the second magnetic field as sensed by the DUT sensor assembly held at the first test orientation O1 may be verified to be within any particular test limits of sensor assembly 114;
(10) the north minus south (“NMS”) average for each sensor module held at the first test orientation O1 may be calculated using the determined average values of procedures (5) and (8), such as by calculating the difference between the determined average values of procedures (5) and (8) for each sensor module (e.g., “O1.NMS.Avg.X”=“O1.North.Avg.X”−“O1.South.Avg.X”, “O1.NMS.Avg.Y”=“O1.North.Avg.Y”−“O1.South.Avg.Y”, and “O1.NMS.Avg.Z”=“O1.North.Avg.Z”−“O1.South.Avg.Z”), and then such NMS averages as sensed by the DUT sensor assembly held at the first test orientation O1 may be verified to be within any particular test limits of sensor assembly 114 (e.g., −200 microteslas to −140 microteslas for each axis NMS average); and
(11) the magnitude of NMS as sensed by the DUT sensor assembly held at the first test orientation O1 may be calculated using the calculated values of procedure (10), such as by calculating the square root of the sum of the squares of the calculated values of procedure (10) (e.g., “O1.NMS.Magnitude”=√((“O1.NMS.Avg.X”)²+(“O1.NMS.Avg.Y”)²+(“O1.NMS.Avg.Z”)²)), and then such a magnitude of NMS as sensed by the DUT sensor assembly held at the first test orientation O1 may be verified to be within any particular test limits of sensor assembly 114 (e.g., +250 microteslas to +350 microteslas).
   Additionally or alternatively, when holder 214 and sensor assembly 115 are held at a second particular test orientation (“O2”) with respect to the coil pair C-axis (e.g., the test orientation of FIG. 3A), one or more of the following procedures may be carried out (e.g., at test station 200):
(12) when no magnetic field is applied by test station 200 along the coil C-axis, a certain number of output data readings from each sensor module of a particular sensor assembly held at the second test orientation O2 may be collected that may be indicative of any magnetic field sensed by each sensor module (e.g., 100 output data readings from each one of X-axis magnetometer sensor module 114x, Y-axis magnetometer sensor module 114y, and Z-axis magnetometer sensor module 114z may be collected when a sample rate of magnetometer sensor assembly 114 is set to 100 hertz and output data is collected for 1 second);
(13) average values of the number of output data readings collected by procedure (12) (e.g., when no magnetic field is applied by test station 200 along the coil C-axis) may be determined for each sensor module held at the second test orientation O2 (e.g., “O2.None.Avg.X” for X-axis magnetometer sensor module 114x, “O2.None.Avg.Y” for Y-axis magnetometer sensor module 114y, and “O2.None.Avg.Z” for Z-axis magnetometer sensor module 114z), and then such average output data values as sensed by the DUT sensor assembly held at the second test orientation O2 may be verified to be within any particular test limits of sensor assembly 114 (e.g., a range between −1200 microteslas to +1200 microteslas for each sensor axis sensor module);
(14) standard deviation values for the output data readings collected by procedure (12) (e.g., when no magnetic field is applied by test station 200 along the coil C-axis) may be determined for each sensor module held at the second test orientation O2 (e.g., “O2.None.Std.X” for X-axis magnetometer sensor module 114x, “O2.None.Std.Y” for Y-axis magnetometer sensor module 114y, and “O2.None.Std.Z” for Z-axis magnetometer sensor module 114z), and then such standard deviation values may be verified to be within any particular test limits of sensor assembly 114 (e.g., a range between 0 microteslas to 0.5 microteslas for each sensor axis sensor module);
(15) when a first or north magnetic field is applied by test station 200 along the +C-direction of the coil C-axis away from second coil 210 towards first coil 208 (e.g., a north magnetic field of 150 microteslas), a certain number of output data readings from each sensor module of a particular sensor assembly held at the second test orientation O2 may be collected that may be indicative of any magnetic field sensed by each sensor module (e.g., 100 output data readings for each one of X-axis magnetometer sensor module 114x, Y-axis magnetometer sensor module 114y, and Z-axis magnetometer sensor module 114z may be collected when a sample rate of magnetometer sensor assembly 114 is set to 100 hertz and output data is collected for 1 second);
(16) average values of the number of output data readings of procedure (15) (e.g., when a first or north magnetic field is applied by test station 200 along the +C-direction of the coil C-axis) may be determined for each sensor module held at the second test orientation O2 (e.g., “O2.North.Avg.X” for X-axis magnetometer sensor module 114x, “O2.North.Avg.Y” for Y-axis magnetometer sensor module 114y, and “O2.North.Avg.Z” for Z-axis magnetometer sensor module 114z), and then such average output data values as sensed by the DUT sensor assembly held at the second test orientation O2 may be verified to be within any particular test limits of sensor assembly 114;
(17) the magnitude of the first magnetic field as sensed by the DUT sensor assembly held at the second test orientation O2 may be calculated using the determined average values of procedure (16), such as by calculating the square root of the sum of the squares of the determined average values of procedure (16) (e.g., “O2.North.Mag”=√((“O2.North.Avg.X”)²+(“O2.North.Avg.Y”)²+(“O2.North.Avg.Z”)²)), and then such a magnitude of the first magnetic field as sensed by the DUT sensor assembly held at the second test orientation O2 may be verified to be within any particular test limits of sensor assembly 114;
(18) when a second or south magnetic field is applied by test station 200 along the −C-direction of the coil C-axis away from first coil 208 towards second coil 210 (e.g., a south magnetic field of 150 microteslas), a certain number of output data readings from each sensor module of a particular sensor assembly held at the second test orientation O2 may be collected that may be indicative of any magnetic field sensed by each sensor module (e.g., 100 output data readings for each one of X-axis magnetometer sensor module 114x, Y-axis magnetometer sensor module 114y, and Z-axis magnetometer sensor module 114z may be collected when a sample rate of magnetometer sensor assembly 114 is set to 100 hertz and output data is collected for 1 second);
(19) average values of the number of output data readings of procedure (18) (e.g., when a second or south magnetic field is applied by test station 200 along the −C-direction of the coil C-axis) may be determined for each sensor module held at the second test orientation O2 (e.g., “O2.South.Avg.X” for X-axis magnetometer sensor module 114x, “O2.South.Avg.Y” for Y-axis magnetometer sensor module 114y, and “O2.South.Avg.Z” for Z-axis magnetometer sensor module 114z), and then such average output data values as sensed by the DUT sensor assembly held at the second test orientation O2 may be verified to be within any particular test limits of sensor assembly 114;
(20) the magnitude of the second magnetic field as sensed by the DUT sensor assembly held at the second test orientation O2 may be calculated using the determined average values of procedure (19), such as by calculating the square root of the sum of the squares of the determined average values of procedure (19) (e.g., “O2.South.Mag”=√((“O2.South.Avg.X”)²+(“O2.South.Avg.Y”)²+(“O2.South.Avg.Z”)²)), and then such a magnitude of the second magnetic field as sensed by the DUT sensor assembly held at the second test orientation O2 may be verified to be within any particular test limits of sensor assembly 114;
(21) the north minus south (“NMS”) average for each sensor module held at the second test orientation O2 may be calculated using the determined average values of procedures (16) and (19), such as by calculating the difference between the determined average values of procedures (16) and (19) for each sensor module (e.g., “O2.NMS.Avg.X”=“O2.North.Avg.X”−“O2.South.Avg.X”, “O2.NMS.Avg.Y”=“O2.North.Avg.Y”−“O2.South.Avg.Y”, and “O2.NMS.Avg.Z”=“O2.North.Avg.Z”−“O2.South.Avg.Z”), and then such NMS averages as sensed by the DUT sensor assembly held at the second test orientation O2 may be verified to be within any particular test limits of sensor assembly 114 (e.g., −200 microteslas to −140 microteslas for each axis NMS average); and
(22) the magnitude of NMS as sensed by the DUT sensor assembly held at the second test orientation O2 may be calculated using the calculated values of procedure (21), such as by calculating the square root of the sum of the squares of the calculated values of procedure (21) (e.g., “O2.NMS.Magnitude”=√((“O2.NMS.Avg.X”)²+(“O2.NMS.Avg.Y”)²+(“O2.NMS.Avg.Z”)²)), and then such a magnitude of NMS as sensed by the DUT sensor assembly held at the second test orientation O2 may be verified to be within any particular test limits of sensor assembly 114 (e.g., +250 microteslas to +350 microteslas).
   Additionally or alternatively, when holder 214 and sensor assembly 115 are held at a third particular test orientation (“O3”) with respect to the coil pair C-axis (e.g., the test orientation of FIG. 3B), one or more of the following procedures may be carried out (e.g., at test station 200):
(23) when no magnetic field is applied by test station 200 along the coil C-axis, a certain number of output data readings from each sensor module of a particular sensor assembly held at the third test orientation O3 may be collected that may be indicative of any magnetic field sensed by each sensor module (e.g., 100 output data readings from each one of X-axis magnetometer sensor module 114x, Y-axis magnetometer sensor module 114y, and Z-axis magnetometer sensor module 114z may be collected when a sample rate of magnetometer sensor assembly 114 is set to 100 hertz and output data is collected for 1 second);
(24) average values of the number of output data readings collected by procedure (23) (e.g., when no magnetic field is applied by test station 200 along the coil C-axis) may be determined for each sensor module held at the third test orientation O3 (e.g., “O3.None.Avg.X” for X-axis magnetometer sensor module 114x, “O3.None.Avg.Y” for Y-axis magnetometer sensor module 114y, and “O3.None.Avg.Z” for Z-axis magnetometer sensor module 114z), and then such average output data values as sensed by the DUT sensor assembly held at the third test orientation O3 may be verified to be within any particular test limits of sensor assembly 114 (e.g., a range between −1200 microteslas to +1200 microteslas for each sensor axis sensor module);
(25) standard deviation values for the output data readings collected by procedure (23) (e.g., when no magnetic field is applied by test station 200 along the coil C-axis) may be determined for each sensor module held at the third test orientation O3 (e.g., “O3.None.Std.X” for X-axis magnetometer sensor module 114x, “O3.None.Std.Y” for Y-axis magnetometer sensor module 114y, and “O3.None.Std.Z” for Z-axis magnetometer sensor module 114z), and then such standard deviation values may be verified to be within any particular test limits of sensor assembly 114 (e.g., a range between 0 microteslas to 0.5 microteslas for each sensor axis sensor module);
(26) when a first or north magnetic field is applied by test station 200 along the +C-direction of the coil C-axis away from second coil 210 towards first coil 208 (e.g., a north magnetic field of 150 microteslas), a certain number of output data readings from each sensor module of a particular sensor assembly held at the third test orientation O3 may be collected that may be indicative of any magnetic field sensed by each sensor module (e.g., 100 output data readings for each one of X-axis magnetometer sensor module 114x, Y-axis magnetometer sensor module 114y, and Z-axis magnetometer sensor module 114z may be collected when a sample rate of magnetometer sensor assembly 114 is set to 100 hertz and output data is collected for 1 second);
(27) average values of the number of output data readings of procedure (26) (e.g., when a first or north magnetic field is applied by test station 200 along the +C-direction of the coil C-axis) may be determined for each sensor module held at the third test orientation O3 (e.g., “O3.North.Avg.X” for X-axis magnetometer sensor module 114x, “O3.North.Avg.Y” for Y-axis magnetometer sensor module 114y, and “O3.North.Avg.Z” for Z-axis magnetometer sensor module 114z), and then such average output data values as sensed by the DUT sensor assembly held at the third test orientation O3 may be verified to be within any particular test limits of sensor assembly 114;
(28) the magnitude of the first magnetic field as sensed by the DUT sensor assembly held at the third test orientation O3 may be calculated using the determined average values of procedure (27), such as by calculating the square root of the sum of the squares of the determined average values of procedure (27) (e.g., “O3.North.Mag”=√((“O3.North.Avg.X”)²+(“O3.North.Avg.Y”)²+(“O3.North.Avg.Z”)²)), and then such a magnitude of the first magnetic field as sensed by the DUT sensor assembly held at the third test orientation O3 may be verified to be within any particular test limits of sensor assembly 114;
(29) when a second or south magnetic field is applied by test station 200 along the −C-direction of the coil C-axis away from first coil 208 towards second coil 210 (e.g., a south magnetic field of 150 microteslas), a certain number of output data readings from each sensor module of a particular sensor assembly held at the third test orientation O03 may be collected that may be indicative of any magnetic field sensed by each sensor module (e.g., 100 output data readings for each one of X-axis magnetometer sensor module 114x, Y-axis magnetometer sensor module 114y, and Z-axis magnetometer sensor module 114z may be collected when a sample rate of magnetometer sensor assembly 114 is set to 100 hertz and output data is collected for 1 second);
(30) average values of the number of output data readings of procedure (29) (e.g., when a second or south magnetic field is applied by test station 200 along the −C-direction of the coil C-axis) may be determined for each sensor module held at the third test orientation O3 (e.g., “O3.South.Avg.X” for X-axis magnetometer sensor module 114x, “O3.South.Avg.Y” for Y-axis magnetometer sensor module 114y, and “O3.South.Avg.Z” for Z-axis magnetometer sensor module 114z), and then such average output data values as sensed by the DUT sensor assembly held at the third test orientation O3 may be verified to be within any particular test limits of sensor assembly 114;
(31) the magnitude of the second magnetic field as sensed by the DUT sensor assembly held at the third test orientation O3 may be calculated using the determined average values of procedure (30), such as by calculating the square root of the sum of the squares of the determined average values of procedure (30) (e.g., “O3.South.Mag”=√((“O3.South.Avg.X”)²+(“O3.South.Avg.Y”)²+(“O3.South.Avg.Z”)²)), and then such a magnitude of the second magnetic field as sensed by the DUT sensor assembly held at the third test orientation O3 may be verified to be within any particular test limits of sensor assembly 114;
(32) the north minus south (“NMS”) average for each sensor module held at the third test orientation O3 may be calculated using the determined average values of procedures (27) and (30), such as by calculating the difference between the determined average values of procedures (27) and (30) for each sensor module (e.g., “O3.NMS.Avg.X”=“O3.North.Avg.X”−“O3.South.Avg.X”, “O3.NMS.Avg.Y”=“O3.North.Avg.Y”−“O3.South.Avg.Y”, and “O3.NMS.Avg.Z”=“O3.North.Avg.Z”−“O3.South.Avg.Z”), and then such NMS averages as sensed by the DUT sensor assembly held at the third test orientation O3 may be verified to be within any particular test limits of sensor assembly 114 (e.g., −200 microteslas to −140 microteslas for each axis NMS average); and
(33) the magnitude of NMS as sensed by the DUT sensor assembly held at the third test orientation O3 may be calculated using the calculated values of procedure (32), such as by calculating the square root of the sum of the squares of the calculated values of procedure (32) (e.g., “O3.NMS.Magnitude”=√((“O3.NMS.Avg.X”)²+(“O3.NMS.Avg.Y”)²+(“O3.NMS.Avg.Z”)²)), and then such a magnitude of NMS as sensed by the DUT sensor assembly held at the third test orientation O3 may be verified to be within any particular test limits of sensor assembly 114 (e.g., +250 microteslas to +350 microteslas).

Therefore, at each one of three test orientations of holder 214 and the DUT sensor assembly with respect to the coil pair C-axis, an NMS average may be calculated for each axis sensor module of the DUT sensor assembly (e.g., 9 distinct NMS averages may be determined during such a process of procedures (1)-(33), such as an NMS average for each one of X-axis magnetometer sensor module 114x, Y-axis magnetometer sensor module 114y, and Z-axis magnetometer sensor module 114z of magnetometer sensor assembly 114 at each one of a first test orientation, a second test orientation, and a third test orientation). For example, such a collection of 9 NMS averages may be assembled into the following 3×3 “Sensor Axis NMS Average Output Matrix” M1:

$$[ \begin{matrix}O 1. NMS . Avg . X & O 1. NMS . Avg . Y & O 1. NMS . Avg . Z \\ O 2. NMS . Avg . X & O 2. NMS . Avg . Y & O 2. NMS . Avg . Z \\ O 3. NMS . Avg . X & O 3 NMS . Avg . Y & O 3 NMS . Avg . Z\end{matrix} ] , \qquad ( M1 )$$

where matrix elements “O1.NMS.Avg.X”, “O1.NMS.Avg.Y”, and “O1.NMS.Avg.Z” of matrix M1 may be the respective NMS averages for sensor axes Xs, Ys, and Zs of magnetometer assembly 114 when held at the first test orientation O1 as may be calculated at procedure (10), where matrix elements “O2.NMS.Avg.X”, “O2.NMS.Avg.Y”, and “O2.NMS.Avg.Z” of matrix M1 may be the respective NMS averages for sensor axes Xs, Ys, and Zs of magnetometer assembly 114 when held at the second test orientation O2 as may be calculated at procedure (21), and where matrix elements “O3.NMS.Avg.X”, “O3.NMS.Avg.Y”, and “O3.NMS.Avg.Z” of matrix M1 may be the respective NMS averages for sensor axes Xs, Ys, and Zs of magnetometer assembly 114 when held at the third test orientation O3 as may be calculated at procedure (32). Although each one of procedures (1), (4), (7), (12), (15), (18), (23), (26), and (29) is described with respect to 100 output data readings from each sensor module that may be collected for a 1 second interval when a sample rate of a sensor assembly is set to 100 hertz, it is to be understood that each procedure may be utilized to collect any suitable number of output data readings (e.g., 1, 2, 100, 200, 900, etc.) that may be collected over any suitable period of time when the sensor assembly is set to any suitable output frequency.

The NMS average output elements of such a sensor axis NMS average output matrix M1, as may be determined through various ones of the procedures (1)-(33), may be leveraged to calculate various sensitivity performances of the DUT sensor assembly, such as a main-axis sensitivity performance and two cross-axis sensitivity performances for each axis sensor module of magnetometer sensor assembly 114 (e.g., 9 distinct sensitivity performances may be determined using output matrix M1, such as a main-axis sensitivity performance for each one of X-axis magnetometer sensor module 114x, Y-axis magnetometer sensor module 114y, and Z-axis magnetometer sensor module 114z of magnetometer sensor assembly 114, a first cross-axis sensitivity performance for each one of X-axis magnetometer sensor module 114x, Y-axis magnetometer sensor module 114y, and Z-axis magnetometer sensor module 114z of magnetometer sensor assembly 114 with respect to a first particular other axis sensor module of magnetometer sensor assembly 114, and a second cross-axis sensitivity performance for each one of X-axis magnetometer sensor module 114x, Y-axis magnetometer sensor module 114y, and Z-axis magnetometer sensor module 114z of magnetometer sensor assembly 114 with respect to a second particular other axis sensor module of magnetometer sensor assembly 114). For example, such a collection of 9 distinct sensitivity performances may be assembled into the following 3×3 “Sensor Axis Sensitivity Performance Matrix” M2:

$$[ \begin{matrix}Sxx & Syx & Szx \\ Sxy & Syy & Szy \\ Sxz & Syz & Szz\end{matrix} ] , \qquad ( M2 )$$

where matrix element “Sxx” of matrix M2 may be a main-axis sensitivity performance of the X-axis magnetometer sensor module 114x for detection of a magnetic field on the Xs-sensor axis, where matrix element “Syx” of matrix M2 may be a cross-axis sensitivity performance of the Y-axis magnetometer sensor module 114y for detection of a magnetic field on the Xs-sensor axis, where matrix element “Szx” of matrix M2 may be a cross-axis sensitivity performance of the Z-axis magnetometer sensor module 114z for detection of a magnetic field on the Xs-sensor axis, where matrix element “Sxy” of matrix M2 may be a cross-axis sensitivity performance of the X-axis magnetometer sensor module 114x for detection of a magnetic field on the Ys-sensor axis, where matrix element “Syy” of matrix M2 may be a main-axis sensitivity performance of the Y-axis magnetometer sensor module 114y for detection of a magnetic field on the Ys-sensor axis, where matrix element “Szy” of matrix M2 may be a cross-axis sensitivity performance of the Z-axis magnetometer sensor module 114z for detection of a magnetic field on the Ys-sensor axis, where matrix element “Sxz” of matrix M2 may be a cross-axis sensitivity performance of the X-axis magnetometer sensor module 114x for detection of a magnetic field on the Zs-sensor axis, where matrix element “Syz” of matrix M2 may be a cross-axis sensitivity performance of the Y-axis magnetometer sensor module 114y for detection of a magnetic field on the Zs-sensor axis, and where matrix element “Szz” of matrix M2 may be a main-axis sensitivity performance of the Z-axis magnetometer sensor module 114z for detection of a magnetic field on the Zs-sensor axis. Test station 200 may be leveraged to solve for these sensitivity performances for determining measurements of the DUT sensor assembly's heading direction error in multiple orientations resulting from performance non-idealities in the sensor assembly itself and/or combined with device level effects, such as static magnetic field sources (e.g., receiver, speaker, camera, etc.) and AC varying electromagnetic field sources (e.g., ground return current on the main logic board or through the housing 101) within device 100 providing the sensor assembly.

The sensitivity performance elements of such a sensor axis sensitivity performance matrix M2 may be calculated (e.g., solved for) using the NMS average output elements of sensor axis NMS average output matrix M1 in combination with not only the NMS magnetic field magnitude of the coil pair during the testing process of test station 200 (e.g., the sum of the absolute values of the magnitudes of the two opposite fields of the coil pair (e.g., 300 microteslas when each one of the applied north field and the applied south field is 150 microteslas for each one of procedures (4)-(9), (15)-(20), (26)-(31))) but also in combination with a “Coil Magnetic Field Vector Component on Sensor Axis Rotation Matrix” M3 that be representative of the proportion of the coil pair's magnetic field vector component on a particular sensor axis of a DUT sensor assembly at a particular test orientation (e.g., based on the angle formed by the C-axis and a particular sensor axis at a particular test orientation). Such a coil magnetic field vector component on sensor axis rotation matrix M3 may include 9 field vector components, such as a coil pair magnetic field vector component on each one of the Xs-sensor axis of X-axis magnetometer sensor module 114x, the Ys-sensor axis of Y-axis magnetometer sensor module 114y, and the Zs-sensor axis of Z-axis magnetometer sensor module 114z of magnetometer sensor assembly 114 at each one of the first test orientation, the second test orientation, and the third test orientation). For example, such a collection of 9 field vector components may be assembled into the following 3×3 “Coil Magnetic Field Vector Component on Sensor Axis Rotation Matrix” M3:

$$[ \begin{matrix}O 1. V . C . X & O 1. V . C . Y & O 1. V . C . Z \\ O 2. V . C . X & O 2. V . C . Y & O 2. V . C . Z \\ O 3. V . C . X & O 2. V . C . Y & O 3. V . C . Z\end{matrix} ] , \qquad ( M3 )$$

where matrix element “O1.V.C.X” of matrix M3 may be the proportion of the coil pair's magnetic field vector component on the Xs-sensor axis at the first test orientation O1, where matrix element “O1.V.C.Y” of matrix M3 may be the proportion of the coil pair's magnetic field vector component on the Ys-sensor axis at the first test orientation O1, where matrix element “O1.V.C.Z” of matrix M3 may be the proportion of the coil pair's magnetic field vector component on the Zs-sensor axis at the first test orientation O1, where matrix element “O2.V.C.X” of matrix M3 may be the proportion of the coil pair's magnetic field vector component on the Xs-sensor axis at the second test orientation O2, where matrix element “O2.V.C.Y” of matrix M3 may be the proportion of the coil pair's magnetic field vector component on the Ys-sensor axis at the second test orientation O2, where matrix element “O2.V.C.Z” of matrix M3 may be the proportion of the coil pair's magnetic field vector component on the Zs-sensor axis at the second test orientation O2, where matrix element “O3.V.C.X” of matrix M3 may be the proportion of the coil pair's magnetic field vector component on the Xs-sensor axis at the third test orientation O3, where matrix element “O3.V.C.Y” of matrix M3 may be the proportion of the coil pair's magnetic field vector component on the Ys-sensor axis at the third test orientation O3, and where matrix element “O3.V.C.Z” of matrix M3 may be the proportion of the coil pair's magnetic field vector component on the Zs-sensor axis at the third test orientation O3.

In the particular embodiment of a first test orientation O1 of FIG. 3, where θX, θY, and θZ may be equal to one another such that “O1.V.C.X” and “O1.V.C.Y” and “O1.V.C.Z” may be equal to one another, each one of matrix elements “O1.V.C.X” and “O1.V.C.Y” and “O1.V.C.Z” of matrix M3 may equal “1/√3” such that the root of the sum of the squares of “O1.V.C.X” and “O1.V.C.Y” and “O1.V.C.Z” may equal “1”. In the particular embodiment of a second test orientation O2 of FIG. 3A, where θY′ may be equal to θY such that matrix element “O2.V.C.Y” of matrix M3 may be equal to “O1.V.C.Y” as “1/√3”, and where θZ′ may be 90° such that matrix element “O2.V.C.Z” of matrix M3 may be equal to “0”, matrix element “O2.V.C.X” of matrix M3 may be “√2/√3” such that the root of the sum of the squares of “O2.V.C.X” and “O2.V.C.Y” and “O2.V.C.Z” may equal “1”. In the particular embodiment of a third test orientation O1 of FIG. 3B, where θY″ may be equal to θY such that matrix element “O3.V.C.Y” of matrix M3 may be equal to “O1.V.C.Y” as “1/√3”, and where θX″ may be 90° such that matrix element “O3.V.C.X” of matrix M3 may be equal to “0”, matrix element “O3.V.C.Y” of matrix M3 may be “√2/√3” such that the root of the sum of the squares of “O3.V.C.X” and “O3.V.C.Y” and “O3.V.C.Z” may equal “1”.

The sensitivity performance elements of sensor axis sensitivity performance matrix M2 may be calculated using the NMS average output elements of sensor axis NIMS average output matrix M1 in combination with not only the NMS magnetic field magnitude of the coil pair during the testing process of test station 200 but also in combination with the field vector component elements of coil magnetic field vector component on sensor axis rotation matrix M3 by solving any suitable equation. For example, sensor axis NMS average output matrix M1 may be equal to the product of the NMS magnetic field magnitude and sensor axis sensitivity performance matrix M2 and sensor axis rotation matrix M3 (e.g., M1=NMS×M3×M2). Such an equation, as identified by the following equation E1, may be leveraged to solve for the sensitivity performance elements of sensor axis sensitivity performance matrix M2:

$$[ \begin{matrix}O 1. NMS . Avg . X & O 1. NMS . Avg . Y & O 1. NMS . Avg . Z \\ O 2. NMS . Avg . X & O 2. NMS . Avg . Y & O 2. NMS . Avg . Z \\ O 3. NMS . Avg . X & O 3 NMS . Avg . Y & O 3 NMS . Avg . Z\end{matrix} ] = NMS \times [ \begin{matrix}O 1. V . C . X & O 1. V . C . Y & O 1. V . C . Z \\ O 2. V . C . X & O 2. V . C . Y & O 2. V . C . Z \\ O 3. V . C . X & O 2. V . C . Y & O 3. V . C . Z\end{matrix} ] \times [ \begin{matrix}Sxx & Syx & Szx \\ Sxy & Syy & Szy \\ Sxz & Syz & Szz\end{matrix} ] . \qquad ( E1 )$$

Therefore, at a procedure (34), for example, the conversion matrix of equation E1 may be utilized to calculate the main-axis and cross-axis sensitivity performances for each axis sensor module of magnetometer sensor assembly 114 (e.g., to solve for the elements of matrix M2).

When each one of the sensitivity performance elements of sensor axis sensitivity performance matrix M2 is solved for using equation E1 (e.g., sensitivity performance elements Sxx, Syx, Szx, Sxy, Syy, Szy, Sxz, Syz, and Szz), each solved for sensitivity performance may be compared to an associated sensitivity error limit or an associated standard threshold sensitivity performance for a respective axis of magnetometer sensor assembly 114 or any other suitable comparison data (e.g., data 105) in order to determine whether or not the DUT sensor assembly should be accepted or flagged for further analysis (e.g., if any one or more of the solved for sensitivity performances is +/−10% off from an associated standard threshold sensitivity performance, then the DUT magnetometer sensor assembly 114 may be flagged for further analysis). For example, test limits may be 0.9-1.0 for each one of Sxx, Syy, and Szz, and/or may be 0.05-0.06 for each one of Syx, Szx, Sxy, Szy, Sxz, and Syz. Therefore, this testing of a DUT sensor assembly by testing station 200 may be operative to solve for all 9 sensitivity performance parameters using just three testing orientations of the DUT sensor assembly with respect to a fixed coil pair.

As mentioned, a compass rotation matrix (e.g., a device-sensor rotation matrix) that may map raw compass sensor axes (e.g., sensor axes Xs, Ys, Zs) of magnetometer sensor assembly 114 to device axes (e.g., device axes Xd, Yd, Zd) of electronic device 100 (e.g., with respect to housing 101) may be determined (e.g., at an IMU calibration testing station of factory subsystem 20). Such a device-sensor rotation matrix may also be utilized in equation E1 if applicable (e.g., the product of sensor axis NMS average output matrix M1 and such a device-sensor rotation matrix may be equal to the product of the NMS magnetic field magnitude and sensor axis sensitivity error matrix M2 and sensor axis rotation matrix M3.

In some embodiments, test station 200 may be provided with any suitable alignment detection components for determining whether or not the particular orientation of holder 214 with respect to a fixed portion of test station 200 (e.g., base component 202 and/or the coil pair C-axis) is as desired for a particular test orientation. For example, one or more transmitter/receiver pairs (e.g., laser diode/photodiode pairs) may be provided for detecting proper alignment of holder 214 with respect to a fixed portion of test station 200. As shown in FIGS. 2 and 2A, for example, a first alignment detection support 228 may extend from a first portion of base component 202 and may include a first transmitter 228a, a second transmitter 228b, and third transmitter 228c, while a second alignment detection support 230 may extend from a second portion of base component 202 and may include a first receiver 230a, a second receiver 230b, and third receiver 230c. First transmitter 228a and third receiver 230c may be positioned such that radiation (e.g., a laser) may be communicated from first transmitter 228a (e.g., a laser diode) and received by third receiver 230c (e.g., a photodiode) only when holder 214 is oriented at the test orientation of FIG. 3A (e.g., along a back surface 214k of holder 214, otherwise holder 214 may be oriented so as to block such radiation), second transmitter 228b and second receiver 230b may be positioned such that radiation (e.g., a laser) may be communicated from second transmitter 228b (e.g., a laser diode) and received by second receiver 230b (e.g., a photodiode) only when holder 214 is oriented at the test orientation of FIG. 3 (e.g., along a back surface 214k of holder 214, otherwise holder 214 may be oriented so as to block such radiation), and/or third transmitter 228c and first receiver 230a may be positioned such that radiation (e.g., a laser) may be communicated from third transmitter 228c (e.g., a laser diode) and received by first receiver 230a (e.g., a photodiode) only when holder 214 is oriented at the test orientation of FIG. 3B (e.g., along a back surface 214k of holder 214, otherwise holder 214 may be oriented so as to block such radiation). If radiation is not received properly for the transmitter/receiver pair associated with the test orientation intended to be maintained by holder 214, then the device under test may not be tested until the intended test orientation is properly achieved. Such alignment detection components of test station 200 (e.g., one or more optical transmitter/receiver pairs) may be operative to calibrate each test orientation of holder 214, such that an angle error for each test orientation may be minimized or avoided.

Alternatively or additionally, reference sensor 232 may be leveraged to determine the current orientation of holder 214 with respect to the coil pair C-axis. For example, reference sensor 232 may be configured as an ideal reference sensor 232 whose outputs are trusted by test station 200. Reference sensor 232 may be held by holder 232 in any suitable manner for positioning sensor 232 with respect to coil pair C-axis in a similar manner as the DUT is to be positioned during testing. For example, as shown in FIG. 2B, reference sensor 232 may be held with respect to holder 214 as close as possible to the sensor assembly of the DUT being tested (e.g., as close as possible to the position of sensor assembly center 115c with respect to holder 214) or may be positioned in the same exact location as the DUT with respect to holder 214 (e.g., interchangeably rather than concurrently as shown in the configuration of FIG. 2B). In any event, reference sensor 232 may be leveraged to determine whether holder 214 is appropriately oriented with respect to the C-axis in order to ensure that the testing procedures carried out with respect to the DUT sensor assembly may be adequate. For example, in order to determine that holder 214 is properly oriented at the test orientation of FIG. 3, reference sensor 232 may be operative to detect the magnitude of the magnetic field applied along the C-axis when holder 214 is intended to be at that test orientation, and test station 200 may be operative to determine whether the magnitudes of the magnetic fields sensed by the respective three sensor axes of reference sensor 232 are equal and, if so, may then determine that the current test orientation of holder 214 is indeed the intended test orientation of FIG. 3. As another example, in order to determine that holder 214 is properly oriented at the test orientation of FIG. 3A, reference sensor 232 may be operative to detect the magnitude of the magnetic field applied along the C-axis when holder 214 is intended to be at that test orientation, and test station 200 may be operative to determine whether the magnitude of the magnetic field sensed by the Z-sensor axis of reference sensor 232 is equal to zero and, if so, may then determine that the current test orientation of holder 214 is indeed the intended test orientation of FIG. 3A. As yet another example, in order to determine that holder 214 is properly oriented at the test orientation of FIG. 3B, reference sensor 232 may be operative to detect the magnitude of the magnetic field applied along the C-axis when holder 214 is intended to be at that test orientation, and test station 200 may be operative to determine whether the magnitude of the magnetic field sensed by the X-sensor axis of reference sensor 232 is equal to zero and, if so, may then determine that the current test orientation of holder 214 is indeed the intended test orientation of FIG. 3B. Such leveraging of reference sensor 232 for confirming proper orientation of holder 214 with respect to the C-axis may be done at any suitable juncture, such as once a day, every few hours, before testing any particular DUT, or the like. Such leveraging of reference sensor 232 for confirming proper orientation of holder 214 with respect to the C-axis may be done in addition to or as an alternative to alignment detection supports 228/230. Moreover, reference sensor 232 may be leveraged for routinely checking and/or calibrating any other aspect of test station 200, such as to confirm the desired characteristics of the coil pair (e.g., NMS, etc.), for ensuring appropriate performance of test station 200 (e.g., using a reference ideal magnetometer). By only leveraging one coil pair for the testing procedures of test station 200, only one coil pair may need to be tested or calibrated, and such a coil pair may be made of higher quality than if multiple coil pairs were required to be used in a single test station limited by a certain budget. Therefore, test station 200 may enable efficient, repeatable, and reliable DUT sensor testing in a main line of factory subsystem 20.

Although the three specific test orientations of FIGS. 3, 3A, and 3B are used to describe certain examples of a testing procedure that may be enabled by testing station 200 on a DUT sensor assembly, it is to be understood that a set of any three different test orientations of holder 214 with respect to the C-axis may be used to carry out the testing of this disclosure (e.g., for calculating the sensitivity performance elements of sensor axis sensitivity performance matrix M2 and validating or rejecting the DUT accordingly). More than three orientations may be used to calibrate a fixture alignment issue and/or to calibrate non-ideality of the sensitivity distortion within the system. However, the particular test orientations of FIGS. 3, 3A, and 3B may make certain portions of such testing more efficient (e.g., the test orientation of FIG. 3 that has equal angles between the C-axis and each DUT sensor axis may enable the efficient leveraging of reference sensor 232 for confirming such orientation of holder 214 with respect to the C-axis by detecting equal magnetic fields on each sensor axis, the test orientation of FIG. 3A that has the C-axis perpendicular to a first particular DUT sensor axis may enable the efficient leveraging of reference sensor 232 for confirming such orientation of holder 214 with respect to the C-axis by detecting zero magnetic field on that particular sensor axis, and the test orientation of FIG. 3B that has the C-axis perpendicular to a second particular DUT sensor axis may enable the efficient leveraging of reference sensor 232 for confirming such orientation of holder 214 with respect to the C-axis by detecting zero magnetic field on that particular sensor axis). By utilizing three different test orientations, where second and third ones of the test orientations are achieved by rotating holder 214 from a first test orientation about a particular axis by 45° yet in opposite respective directions (e.g., R1θ and R2θ may each be 45° about axis R in opposite directions), not only may each one of the second and third orientations be enabled to align the C-axis with a particular respective plane shared by two of the sensor axes of the DUT sensor assembly, but also may minimize the total rotation of holder 214 to 900, which may enable test station 200 to be more compact and/or user friendly and/or able to use a simpler motor 216 (e.g., to reduce costs with a simple motor that may have its two maximum testing rotation angles hardcoded). In some embodiments, as shown, a testing orientation or an orientation of holder 214 in between utilized testing orientations may be operative to enable easy positioning of a DUT within holder 214. For example, as shown in the test orientation of FIGS. 2-3, the Xs, Ys, and Zs sensor axes of the DUT may be aligned with the Xt, Yt, and Zt test station axes of test station 200, where such a Zt axis may be generally aligned with the earth's gravity, such that the DUT of device 100 may be easily laid on the Xd-Yd planar back surface 101k of device 100 in holder 214, which may be easily accessible between coils 208 and 210 (e.g., in the −Zt direction). In some embodiments, any three different orientations of sensor assembly 115 with respect to the C-axis that may include sensor assembly center 115c on the C-axis may be leveraged for the testing of sensor assembly 115 by test station 200.

Test station 200 may be operative to test other sensor assemblies of DUT sensor assembly 115 at the same time as magnetometer sensor assembly 114. For example, although accelerometer sensor assembly 116 may be calibrated at another test station of factory subsystem 20 (e.g., an IMU tester may do offset calibration of accelerometer sensor assembly 116 prior to sensor assembly 115 being utilized at test station 200), test station 200 may be operative to measure the gravity component sensed by each axis accelerometer sensor module of accelerometer sensor assembly 116 when holder 214 and, thus, accelerometer sensor assembly 116 are oriented at each one of the three different test orientations of test station 200 (e.g., when assembly 116 is statically oriented at each test orientation rather than being moved through each test orientation). Then, factory subsystem 20 (e.g., test station 200) may be operative to leverage such measured gravity components to conduct a functionality check for determining whether that earlier calibration was adequate.

All processing of data for the testing processes of test station 200 (e.g., all data deriving, calculating, comparing, etc.) may be carried out by any suitable processor or combination of processors, such as processor 102 of device 100 in coordination with any suitable application 103 (e.g., any suitable testing and/or calibrating applications that may be made accessible to device 100) and/or any suitable processor 234 of test station 200, which may be communicatively coupled to DUT sensor assembly 115 within holder 214 via any suitable bus 235 of test station 200 that may be coupled to I/O interface 11b of device 100 or via any wireless communication with communication component 106 of device 100. Such a processor may also be communicatively coupled to motor 216 for directing motor 216 to manipulate holder 214 between its various test orientations with respect to the C-axis to carry out the test procedures of test station 200. Additionally or alternatively, such a processor may be communicatively coupled to electric charge component 212 for directing electric charge component 212 to manipulate the current through coils 208 and 210 to carry out the test procedures of test station 200.

Test station 200 may enable efficient, repeatable, and reliable DUT sensor testing in a main line of factory subsystem 20. As compared to other test stations that may be operative to test similar aspects of a DUT sensor assembly for ensuring a high performance magnetometer sensor assembly (e.g., a Helmholtz Coil station performing elaborate magnetic field sweeping tests), test station 200 may be smaller due to only requiring a single coil pair and/or may be faster due to only requiring two rotations of motor 216 (e.g., to three orientations).

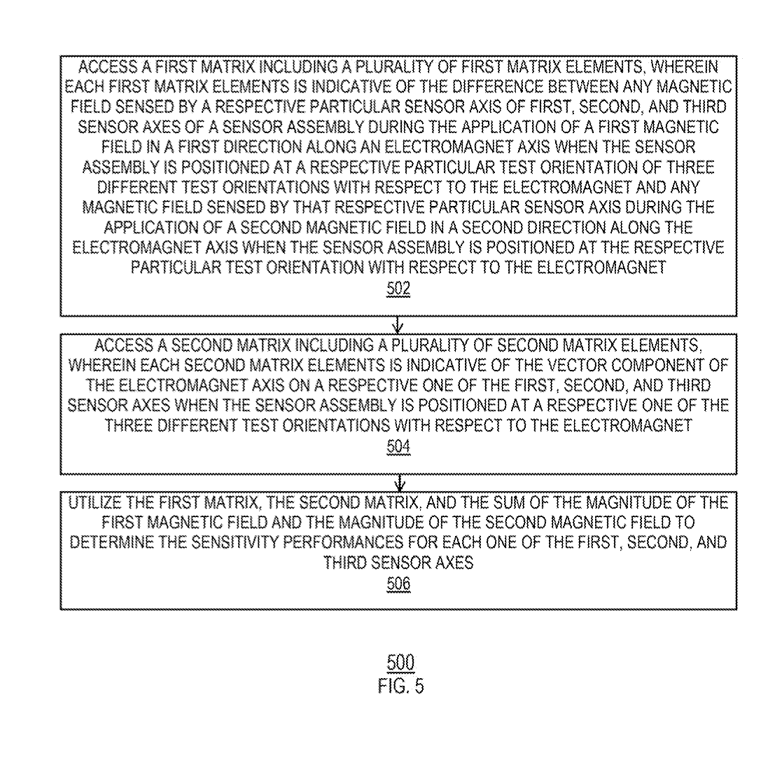

### Description of FIG. 4

FIG. 4 is a flowchart of an illustrative process 400 for testing a sensor assembly that may include a first sensor module with magnetic field sensitivity along a first sensor axis, a second sensor module with magnetic field sensitivity along a second sensor axis that is perpendicular to the first sensor axis, and a third sensor module with magnetic field sensitivity along a third sensor axis that is perpendicular to both the first sensor axis and the second sensor axis (e.g., for testing sensor assembly 114 of sensor assembly 115). At step 402, process 400 may include orienting the sensor assembly at each one of three different test orientations with respect to an electromagnet axis extending between a first electromagnet and a second electromagnet. For example, as described with respect to FIGS. 2-3B, sensor assembly 115 may be oriented at each one of the test orientations of FIG. 3, FIG. 3A, and FIG. 3B with respect to the C-axis. At steps 404 and 406, when the sensor assembly is oriented at each one of the three different test orientations, process 400 may include applying a first magnetic field along the electromagnet axis in a first direction and applying a second magnetic field along the electromagnet axis in a second direction opposite the first direction. For example, as described with respect to FIGS. 2-3B, when sensor assembly 115 is oriented at each one of the test orientations of FIG. 3, FIG. 3A, and FIG. 3B, a first magnetic field NF may be applied along the C-axis in the +C-direction and then a second magnetic field SF may be applied along the C-axis in the −C-direction. At step 408, process 400 may include, for each sensor axis of the first, second, and third sensor axes when oriented at each one of the three different test orientations, determining the difference between any magnetic field sensed by that sensor axis during the application of the first magnetic field and any magnetic field sensed by that sensor axis during the application of the second magnetic field, and at step 410, process 400 may include defining the matrix elements of a first matrix to include the differences determined at step 408. For example, as described with respect to FIGS. 2-3B, a 3×3 sensor axis NMS output matrix M1 may be defined to include the NMS averages for sensor axes Xs, Ys, and Zs of magnetometer assembly 114 when held at each one of first test orientation O1, second test orientation O2, and third test orientation O3. At step 412, process 400 may include defining the matrix elements of a second matrix to include the main-axis sensitivity performance and each one of the two cross-axis sensitivity performances for each one of the first, second, and third sensor axes, and, at step 414, process 400 may include defining the matrix elements of a third matrix to include the vector component of the electromagnet axis on each one of the first, second, and third sensor axes at each one of the three different test orientations. For example, as described with respect to FIGS. 2-3B, a 3×3 sensor axis sensitivity performance matrix M2 may be defined to include the main-axis sensitivity performance and each one of the two cross-axis sensitivity performances for each one of the first, second, and third sensor axes, and a 3×3 coil magnetic field vector component on sensor axis rotation matrix M3 may be defined to include elements based on the angle formed by the C-axis and each particular sensor axis at each particular test orientation. At step 416, process 400 may include determining the value of each matrix element of the second matrix by leveraging an equation that sets the first matrix equal to the product of the sum of the magnitude of the first magnetic field and the magnitude of the second magnetic field, the third matrix, and the second matrix. For example, as described with respect to FIGS. 2-3B, equation E1 may be utilized to calculate the main-axis and cross-axis sensitivity performances for each axis sensor module of magnetometer sensor assembly 114 (e.g., to solve for the elements of matrix M2).

It is understood that the steps shown in process 400 of FIG. 4 are only illustrative and that existing steps may be modified or omitted, additional steps may be added, and the order of certain steps may be altered.

### Description of FIG. 5

FIG. 5 is a flowchart of an illustrative process 500 for testing a sensor assembly with respect to an electromagnet axis, wherein the sensor assembly includes a first sensor module with magnetic field sensitivity along a first sensor axis, a second sensor module with magnetic field sensitivity along a second sensor axis that is perpendicular to the first sensor axis, and a third sensor module with magnetic field sensitivity along a third sensor axis that is perpendicular to both the first sensor axis and the second sensor axis (e.g., for testing sensor assembly 114 of sensor assembly 115). At step 502, process 500 may include accessing a first matrix including a plurality of first matrix elements, wherein each first matrix elements is indicative of the difference between any magnetic field sensed by a respective particular sensor axis of the first, second, and third sensor axes of the sensor assembly during the application of a first magnetic field in a first direction along the electromagnet axis when the sensor assembly is positioned at a respective particular test orientation of three different test orientations with respect to the electromagnet and any magnetic field sensed by that respective particular sensor axis during the application of a second magnetic field in a second direction along the electromagnet axis when the sensor assembly is positioned at the respective particular test orientation with respect to the electromagnet. For example, as described with respect to FIGS. 2-3B, a 3×3 sensor axis NMS output matrix M1 may be defined to include the NMS averages for sensor axes Xs, Ys, and Zs of magnetometer assembly 114 when held at each one of first test orientation O1, second test orientation O2, and third test orientation O3. At step 504, process 500 may include accessing a second matrix including a plurality of second matrix elements, wherein each second matrix elements is indicative of the vector component of the electromagnet axis on a respective one of the first, second, and third sensor axes when the sensor assembly is positioned at a respective one of the three different test orientations with respect to the electromagnet. For example, as described with respect to FIGS. 2-3B, a 3×3 coil magnetic field vector component on sensor axis rotation matrix M3 may be defined to include elements based on the angle formed by the C-axis and each particular sensor axis at each particular test orientation. At step 506, process 500 may include utilizing the first matrix, the second matrix, and the sum of the magnitude of the first magnetic field and the magnitude of the second magnetic field to determine the sensitivity performances for each one of the first, second, and third sensor axes. For example, as described with respect to FIGS. 2-3B, equation E1 may be utilized to calculate the main-axis and cross-axis sensitivity performances for each axis sensor module of magnetometer sensor assembly 114 (e.g., to solve for the elements of matrix M2).

It is understood that the steps shown in process 500 of FIG. 5 are only illustrative and that existing steps may be modified or omitted, additional steps may be added, and the order of certain steps may be altered.

### Further Applications of Described Concepts

One, some, or all of the processes described with respect to FIGS. 1-5 may each be implemented by software, but may also be implemented in hardware, firmware, or any combination of software, hardware, and firmware. Instructions for performing these processes may also be embodied as machine- or computer-readable code recorded on a machine- or computer-readable medium. In some embodiments, the computer-readable medium may be a non-transitory computer-readable medium. Examples of such a non-transitory computer-readable medium include but are not limited to a read-only memory, a random-access memory, a flash memory, a CD-ROM, a DVD, a magnetic tape, a removable memory card, and a data storage device (e.g., memory 104 of FIG. 1). In other embodiments, the computer-readable medium may be a transitory computer-readable medium. In such embodiments, the transitory computer-readable medium can be distributed over network-coupled computer systems so that the computer-readable code is stored and executed in a distributed fashion. For example, such a transitory computer-readable medium may be communicated from one electronic device to another electronic device using any suitable communications protocol (e.g., the computer-readable medium may be communicated from a remote device as data 55 to electronic device 100 via communications component 106 (e.g., as at least a portion of an application 103). Such a transitory computer-readable medium may embody computer-readable code, instructions, data structures, program modules, or other data in a modulated data signal, such as a carrier wave or other transport mechanism, and may include any information delivery media. A modulated data signal may be a signal that has one or more of its characteristics set or changed in such a manner as to encode information in the signal.

It is to be understood that any, each, or at least one suitable module or component or element or subsystem of system 1 may be provided as a software construct, firmware construct, one or more hardware components, or a combination thereof. For example, any, each, or at least one suitable module or component or element or subsystem of system 1 may be described in the general context of computer-executable instructions, such as program modules, that may be executed by one or more computers or other devices. Generally, a program module may include one or more routines, programs, objects, components, and/or data structures that may perform one or more particular tasks or that may implement one or more particular abstract data types. It is also to be understood that the number, configuration, functionality, and interconnection of the modules and components and elements and subsystems of system 1 are only illustrative, and that the number, configuration, functionality, and interconnection of existing modules, components, elements, and/or subsystems of system 1 may be modified or omitted, additional modules, components, elements, and/or subsystems of system 1 may be added, and the interconnection of certain modules, components, elements, and/or subsystems of system 1 may be altered.

At least a portion of one or more of the modules or components or elements or subsystems of system 1 may be stored in or otherwise accessible to an entity of system 1 in any suitable manner (e.g., in memory 104 of device 100 (e.g., as at least a portion of an application 103)) and may be implemented using any suitable technologies (e.g., as one or more integrated circuit devices), and different modules may or may not be identical in structure, capabilities, and operation. Any or all of the modules or other components of system 1 may be mounted on an expansion card, mounted directly on a system motherboard, or integrated into a system chipset component (e.g., into a “north bridge” chip).

While there have been described systems, methods, and computer-readable media for efficiently testing sensor assemblies, it is to be understood that many changes may be made therein without departing from the spirit and scope of the subject matter described herein in any way. Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

Therefore, those skilled in the art will appreciate that the invention can be practiced by other than the described embodiments, which are presented for purposes of illustration rather than of limitation.

What is claimed is:

1. A station for testing a sensor assembly that comprises a first sensor module with magnetic field sensitivity along a first sensor axis, a second sensor module with magnetic field sensitivity along a second sensor axis that is perpendicular to the first sensor axis, and a third sensor module with magnetic field sensitivity along a third sensor axis that is perpendicular to both the first sensor axis and the second sensor axis, the station comprising:
a pair of electromagnets comprising a first electromagnet and a second electromagnet that is held in a fixed relationship with respect to the first electromagnet, wherein the pair of electromagnets is operative to generate at least one magnetic field along an electromagnet axis extending between the first electromagnet and the second electromagnet;
a holder operative to hold the sensor assembly in a fixed relationship with respect to the holder; and
a re-orientation subassembly operative to move the holder between a plurality of test orientations with respect to the electromagnet axis, wherein the plurality of test orientations comprises:
a first test orientation at which the at least one magnetic field forms three identical angles with the first, second, and third sensor axes when the sensor assembly is held by the holder;
a second test orientation at which the at least one magnetic field is both perpendicular to the first sensor axis and in a first plane that comprises the second and third sensor axes when the sensor assembly is held by the holder; and
a third test orientation at which the at least one magnetic field is both perpendicular to the third sensor axis and in a first plane that comprises the first and second sensor axes when the sensor assembly is held by the holder.

2. The station of claim 1, wherein the re-orientation subassembly is operative to rotate the holder about a rotation axis for moving the holder between any two test orientations of the first, second, and third test orientations.

3. The station of claim 2, wherein the rotation axis is aligned with the second sensor axis when the sensor assembly is held by the holder.

4. The station of claim 2, wherein the re-orientation subassembly is operative to:
rotate the holder in a first direction about the rotation axis by a first rotation angle for moving the holder from the first test orientation to the second test orientation; and
rotate the holder in a second direction about the rotation axis by a second rotation angle for moving the holder from the first test orientation to the third test orientation.

5. The station of claim 4, wherein the magnitude of the first rotation angle is equal to the magnitude of the second rotation angle.

6. The station of claim 5, wherein the magnitude of each one of the first rotation angle and the second rotation angle is 45°.

7. The station of claim 1, wherein, when both the sensor assembly is held by the holder and the holder is at any one of the first, second, and third test orientations, an intersection of the first, second, and third sensor axes is positioned on the electromagnet axis.

8. The station of claim 1, wherein, when both the sensor assembly is held by the holder and the holder is at any one of the first, second, and third test orientations, an intersection of the first, second, and third sensor axes is positioned at a location along the electromagnet axis that is equidistant from each one of the first electromagnet and the second electromagnet.

9. The station of claim 1, further comprising a processor operative to:
access a first matrix comprising a plurality of first matrix elements, wherein each first matrix elements is indicative of the difference between any magnetic field sensed by a respective particular sensor axis of the first, second, and third sensor axes of the sensor assembly during the application of a first magnetic field of the at least one magnetic field in a first direction along the electromagnet axis when the sensor assembly is positioned at a respective particular test orientation of the first, second, and third test orientations with respect to the electromagnet axis and any magnetic field sensed by that respective particular sensor axis during the application of a second magnetic field of the at least one magnetic field in a second direction along the electromagnet axis when the sensor assembly is positioned at the respective particular test orientation with respect to the electromagnet;
access a second matrix comprising a plurality of second matrix elements, wherein each second matrix elements is indicative of the vector component of the electromagnet axis on a respective one of the first, second, and third sensor axes when the sensor assembly is at a respective one of the first, second, and third test orientations with respect to the electromagnet; and
utilize the first matrix, the second matrix, and the sum of the magnitude of the first magnetic field and the magnitude of the second magnetic field to determine the sensitivity performances for each one of the first, second, and third sensor axes.

10. The station of claim 1, further comprising a processor, wherein:
when the sensor assembly is held by the holder, when the holder is at the first test orientation, and when a first magnetic field of the at least one magnetic field is generated along the electromagnet axis away from the second electromagnet towards the first electromagnet, the processor is operative to determine:
a first first sensor module value indicative of any magnetic field sensed by the first sensor module;
a first second sensor module value indicative of any magnetic field sensed by the second sensor module; and
a first third sensor module value indicative of any magnetic field sensed by the third sensor module;
when the sensor assembly is held by the holder, when the holder is at the first test orientation, and when a second magnetic field of the at least one magnetic field is generated along the electromagnet axis away from the first electromagnet towards the second electromagnet, the processor is operative to determine:
a second first sensor module value indicative of any magnetic field sensed by the first sensor module;
a second second sensor module value indicative of any magnetic field sensed by the second sensor module; and
a second third sensor module value indicative of any magnetic field sensed by the third sensor module;
when the sensor assembly is held by the holder, when the holder is at the second test orientation, and when the first magnetic field is generated along the electromagnet axis away from the second electromagnet towards the first electromagnet, the processor is operative to determine:
a third first sensor module value indicative of any magnetic field sensed by the first sensor module;
a third second sensor module value indicative of any magnetic field sensed by the second sensor module; and
a third third sensor module value indicative of any magnetic field sensed by the third sensor module;
when the sensor assembly is held by the holder, when the holder is at the second test orientation, and when the second magnetic field is generated along the electromagnet axis away from the first electromagnet towards the second electromagnet, the processor is operative to determine:
a fourth first sensor module value indicative of any magnetic field sensed by the first sensor module;
a fourth second sensor module value indicative of any magnetic field sensed by the second sensor module; and
a fourth third sensor module value indicative of any magnetic field sensed by the third sensor module;
when the sensor assembly is held by the holder, when the holder is at the third test orientation, and when the first magnetic field is generated along the electromagnet axis away from the second electromagnet towards the first electromagnet, the processor is operative to determine:
a fifth first sensor module value indicative of any magnetic field sensed by the first sensor module;
a fifth second sensor module value indicative of any magnetic field sensed by the second sensor module; and
a fifth third sensor module value indicative of any magnetic field sensed by the third sensor module;
when the sensor assembly is held by the holder, when the holder is at the third test orientation, and when the second magnetic field is generated along the electromagnet axis away from the first electromagnet towards the second electromagnet, the processor is operative to determine:
a sixth first sensor module value indicative of any magnetic field sensed by the first sensor module;
a sixth second sensor module value indicative of any magnetic field sensed by the second sensor module; and
a sixth third sensor module value indicative of any magnetic field sensed by the third sensor module;
the processor is operative to define a first matrix comprising the following first matrix elements:
a seventh first sensor module value indicative of the difference between the first first sensor module value and the second first sensor module value;
a seventh second sensor module value indicative of the difference between the first second sensor module value and the second second sensor module value;
a seventh third sensor module value indicative of the difference between the first third sensor module value and the second third sensor module value;
an eighth first sensor module value indicative of the difference between the third first sensor module value and the fourth first sensor module value;
an eighth second sensor module value indicative of the difference between the third second sensor module value and the fourth second sensor module value;
an eighth third sensor module value indicative of the difference between the third third sensor module value and the fourth third sensor module value;
a ninth first sensor module value indicative of the difference between the fifth first sensor module value and the sixth first sensor module value;
a ninth second sensor module value indicative of the difference between the fifth second sensor module value and the sixth second sensor module value; and
a ninth third sensor module value indicative of the difference between the fifth third sensor module value and the sixth third sensor module value; and
a second matrix comprises the following second matrix elements:
a first sensitivity value indicative of a main-axis sensitivity performance of the first sensor module for detecting any magnetic field on the first sensor axis;
a second sensitivity value indicative of a cross-axis sensitivity performance of the second sensor module for detecting any magnetic field on the first sensor axis;
a third sensitivity value indicative of a cross-axis sensitivity performance of the third sensor module for detecting any magnetic field on the first sensor axis;
a fourth sensitivity value indicative of a cross-axis sensitivity performance of the first sensor module for detecting any magnetic field on the second sensor axis;
a fifth sensitivity value indicative of a main-axis sensitivity performance of the second sensor module for detecting any magnetic field on the second sensor axis;
a sixth sensitivity value indicative of a cross-axis sensitivity performance of the third sensor module for detecting any magnetic field on the second sensor axis;
a seventh sensitivity value indicative of a cross-axis sensitivity performance of the first sensor module for detecting any magnetic field on the third sensor axis;
an eighth sensitivity value indicative of a cross-axis sensitivity performance of the second sensor module for detecting any magnetic field on the third sensor axis; and
a ninth sensitivity value indicative of a main-axis sensitivity performance of the third sensor module for detecting any magnetic field on the third sensor axis;
a third matrix comprises the following third matrix elements:
1/√3;
1/√3;
√2/√3;
1/√3;
0;
0;
1/√3; and
√2/√3; and
the processor is operative to determine the value of each second matrix element of the second matrix by leveraging the equation that sets the first matrix equal to the product of the following factors:
the sum of the magnitude of the first magnetic field and the magnitude of the second magnetic field;
the third matrix; and
the second matrix.

11. A method for testing a sensor assembly that comprises a first sensor module with magnetic field sensitivity along a first sensor axis, a second sensor module with magnetic field sensitivity along a second sensor axis that is perpendicular to the first sensor axis, and a third sensor module with magnetic field sensitivity along a third sensor axis that is perpendicular to both the first sensor axis and the second sensor axis, the method comprising:
orienting the sensor assembly at each one of three different test orientations with respect to an electromagnet axis extending between a first electromagnet and a second electromagnet;
when the sensor assembly is oriented at each one of the three different test orientations:
applying a first magnetic field along the electromagnet axis in a first direction; and
applying a second magnetic field along the electromagnet axis in a second direction opposite the first direction;
for each sensor axis of the first, second, and third sensor axes when oriented at each one of the three different test orientations, determining the difference between any magnetic field sensed by that sensor axis during the application of the first magnetic field and any magnetic field sensed by that sensor axis during the application of the second magnetic field;
defining the matrix elements of a first matrix to comprise the determined differences;
defining the matrix elements of a second matrix to comprise the main-axis sensitivity performance and each one of the two cross-axis sensitivity performances for each one of the first, second, and third sensor axes;
defining the matrix elements of a third matrix to comprise the vector component of the electromagnet axis on each one of the first, second, and third sensor axes at each one of the three different test orientations; and
determining the value of each matrix element of the second matrix by leveraging an equation that sets the first matrix equal to the product of the following factors:
the sum of the magnitude of the first magnetic field and the magnitude of the second magnetic field;
the third matrix; and
the second matrix.

12. The method of claim 11, wherein the orienting comprises rotating the sensor assembly about a rotation axis.

13. The method of claim 12, wherein the rotation axis is the second sensor axis.

14. The method of claim 12, wherein the orienting comprises:
rotating the sensor assembly in a first direction about the rotation axis by a first rotation angle for moving the sensor assembly from a first test orientation of the three different test orientations to a second test orientation of the three different test orientations; and
rotating the sensor assembly in a second direction about the rotation axis by a second rotation angle for moving the sensor assembly from the first test orientation to a third test orientation of the three different test orientations.

15. The method of claim 14, wherein the magnitude of the first rotation angle is equal to the magnitude of the second rotation angle.

16. The method of claim 14, wherein the magnitude of each one of the first rotation angle and the second rotation angle is 45°.

17. The method of claim 11, wherein, the orienting the sensor assembly at each one of the three different test orientations comprises positioning an intersection of the first, second, and third sensor axes on the electromagnet axis.

18. The method of claim 11, wherein:
the orienting the sensor assembly at a first test orientation of the three different test orientations comprises positioning the sensor assembly such that the electromagnet axis forms a first angle with the first sensor axis, a second angle with the second sensor axis, and a third angle with the third sensor axis;
the magnitude of the first angle is the same as the magnitude of the second angle;
the magnitude of the first angle is the same as the magnitude of the third angle;
the orienting the sensor assembly at a second test orientation of the three different test orientations comprises positioning the sensor assembly such that the electromagnet axis is both perpendicular to the first sensor axis and in a first plane that comprises the second and third sensor axes; and
the orienting the sensor assembly at a third test orientation of the three different test orientations comprises positioning the sensor assembly such that the electromagnet axis is both perpendicular to the third sensor axis and in a first plane that comprises the first and second sensor axes.

19. A non-transitory computer-readable medium for testing a sensor assembly with respect to an electromagnet axis, wherein the sensor assembly comprises a first sensor module with magnetic field sensitivity along a first sensor axis, a second sensor module with magnetic field sensitivity along a second sensor axis that is perpendicular to the first sensor axis, and a third sensor module with magnetic field sensitivity along a third sensor axis that is perpendicular to both the first sensor axis and the second sensor axis, the non-transitory computer-readable medium comprising computer-readable instructions recorded thereon for:
accessing a first matrix comprising a plurality of first matrix elements, wherein each first matrix elements is indicative of the difference between any magnetic field sensed by a respective particular sensor axis of the first, second, and third sensor axes of the sensor assembly during the application of a first magnetic field in a first direction along the electromagnet axis when the sensor assembly is positioned at a respective particular test orientation of three different test orientations with respect to the electromagnet and any magnetic field sensed by that respective particular sensor axis during the application of a second magnetic field in a second direction along the electromagnet axis when the sensor assembly is positioned at the respective particular test orientation with respect to the electromagnet;
accessing a second matrix comprising a plurality of second matrix elements, wherein each second matrix elements is indicative of the vector component of the electromagnet axis on a respective one of the first, second, and third sensor axes when the sensor assembly is positioned at a respective one of the three different test orientations with respect to the electromagnet; and
utilizing the first matrix, the second matrix, and the sum of the magnitude of the first magnetic field and the magnitude of the second magnetic field to determine the sensitivity performances for each one of the first, second, and third sensor axes.

20. The non-transitory computer-readable medium of claim 19, wherein the sensitivity performances comprise the main-axis sensitivity performance and each one of the two cross-axis sensitivity performances for each one of the first, second, and third sensor axes.
